(19) United States
(12) Patent Application Publication
(10) Pub. No.: US 2025/0294960 A1
(43) Pub. Date: Sep. 18, 2025

(54) LIGHT-EMITTING ELEMENT AND DISPLAY DEVICE INCLUDING THE SAME

(71) Applicant: Samsung Display Co., Ltd., Yongin-si (KR)

(72) Inventors: SEULONG KIM, Yongin-si (KR); SUNHYE LEE, Yongin-si (KR); JAEJIN LEE, Yongin-si (KR); Hyuna LEE, Yongin-si (KR); JAHYUN IM, Yongin-si (KR)

(73) Assignee: Samsung Display Co., Ltd., Yongin-si (KR)

(21) Appl. No.: 19/077,366

(22) Filed: Mar. 12, 2025

(30) Foreign Application Priority Data
Mar. 13, 2024 (KR) 10-2024-0034919

(51) Int. Cl. H10K 50/16; H10K 59/35; H10K 85/60; H10K 102/00

(52) U.S. Cl. CPC H10K 50/166; H10K 59/353; H10K 85/626; H10K 85/654; H10K 85/6574; H10K 2102/351

(57) ABSTRACT

Embodiments provide a light-emitting element and an electronic device that includes the light-emitting element. The light-emitting element includes: a first electrode; a second electrode facing the first electrode; a lower emission structure disposed between the first electrode and the second electrode and including a first lower functional layer, a first emission layer, and a first upper functional layer; an upper emission structure disposed on the lower emission structure and including a second lower functional layer, a second emission layer, and a second upper functional layer; and a charge generation layer disposed between the lower emission structure and the upper emission structure and including an n-type charge generation layer and a p-type charge generation layer, wherein the light-emitting element satisfies Expression 1, which is explained in the specification:

$$50 nm \geq {d}_{TOP} > {d}_{LOW} > 15 nm . \qquad [ Expression 1 ]$$

### CROSS-REFERENCE TO RELATED APPLICATION(S)

This application claims priority to and benefits of Korean Patent Application No. 10-2024-0034919 under 35 U.S.C. § 119, filed on Mar. 13, 2024, in the Korean Intellectual Property Office, the entire contents of which are incorporated herein by reference.

### BACKGROUND

### 1. Technical Field

The disclosure relates to a light-emitting element including multiple emission structures that are stacked, and a display device including the same.

### 2. Description of the Related Art

Ongoing development continues for display devices for various multimedia applications, such as in a television, a mobile phone, a tablet computer, a navigation device, and a game console. These display devices utilize a so-called self-emissive display element that achieves display by causing a light-emitting material, which may include an organic compound or quantum dots, in an emission layer disposed between electrodes facing each other to emit light.

The application of a light-emitting element to a display device requires high light emission efficiency and a long lifespan from the light-emitting element, and continuous development is required for a light-emitting element having a stacked structure and for a material of a light-emitting element that is capable of stably achieving high light emission efficiency and a long lifespan.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element that exhibits improved light emission efficiency and a long lifespan.

The disclosure also provides a display device including a light-emitting element having high light emission efficiency and a long lifespan.

According to an embodiment, a light-emitting element may include: a first electrode; a second electrode facing the first electrode; a lower emission structure disposed between the first electrode and the second electrode, the lower emission structure including a first lower functional layer, a first emission layer, and a first upper functional layer that are sequentially stacked; an upper emission structure disposed on the lower emission structure, the upper emission structure including a second lower functional layer, a second emission layer, and a second upper functional layer that are sequentially stacked; and a charge generation layer disposed between the lower emission structure and the upper emission structure, the charge generation layer including an n-type charge generation layer and a p-type charge generation layer, wherein the light-emitting element may satisfy Expression 1:

$$50 nm \geq {d}_{TOP} > {d}_{LOW} > 15 nm . \qquad [ Expression 1 ]$$

In Expression 1, d_{LOW} may be a sum of a thickness of the first upper functional layer and a thickness of the n-type charge generation layer; and d_{TOP} may be a thickness of the second upper functional layer.

In an embodiment, the first upper functional layer, the second upper functional layer, and the n-type charge generation layer may each include an electron transport material; and the first lower functional layer and the second lower functional layer may each include a hole transport material.

In an embodiment, the first upper functional layer may include a first electron transport layer directly disposed under the n-type charge generation layer, and a first electron transport auxiliary layer directly disposed under the first electron transport layer; and the second upper functional layer may include a second electron transport auxiliary layer directly disposed on the second emission layer, and a second electron transport layer directly disposed on the second electron transport auxiliary layer.

In an embodiment, three or more layers selected from the first electron transport layer, the first electron transport auxiliary layer, the n-type charge generation layer, the second electron transport auxiliary layer, and the second electron transport layer may each independently include an electron transport material including a monocyclic 6-membered heteroaryl group that includes N as a ring-forming atom.

In an embodiment, the electron transport material that is included in at least one layer among the selected three or more layers may include a monocyclic 6-membered heteroaryl group that includes N as a ring-forming atom and a condensed ring that includes eight or more ring-forming carbon atoms.

In an embodiment, the condensed ring may be naphthalene, anthracene, fluorene, phenanthrene, spiro-bifluorene, fluoranthene, chrysene, quinoline, quinazoline, phenanthroline, dibenzofuran, or dibenzothiophene.

In an embodiment, the electron transport material may be a compound selected from Compound Group 1, which is explained below.

In an embodiment, the first emission layer and the second emission layer may emit light in a same wavelength region.

In an embodiment, at least one of the first upper functional layer and the second upper functional layer may each independently include three or more electron transport functional layers; and the electron transport functional layers may each be an electron injection layer, an electron transport layer, or a hole blocking layer.

In an embodiment, at least one of the first lower functional layer and the second lower functional layer may each independently include three or more hole transport functional layers; and the hole transport functional layers may each be a hole injection layer, a hole transport layer, an electron blocking layer, or an emission auxiliary layer.

In an embodiment, the light-emitting element may further include a capping layer disposed on the second electrode.

According to an embodiment, a light-emitting element may include: a first electrode; a second electrode facing the first electrode; multiple emission structures disposed between the first electrode and the second electrode, each emission structure including a lower functional layer, an emission layer, and an upper functional layer that are sequentially stacked; and one or more charge generation layers, each charge generation layer disposed between adjacent emission structures among the emission structures, and each charge generation layer including an n-type charge generation layer and a p-type charge generation layer, wherein the light-emitting element may satisfy Expression 1:

$$50 nm \geq {d}_{TOP} > {d}_{LOW} > 15 nm . \qquad [ Expression 1 ]$$

In Expression 1, d_{LOW} may be a sum of a thickness of the upper functional layer of a lower emission structure that is adjacent to the first electrode and a thickness of the n-type charge generation layer directly disposed on the lower emission structure; and d_{TOP} may be a thickness of the upper functional layer of an upper emission structure that is adjacent to the second electrode.

In an embodiment, the upper functional layer of each emission structure may include an electron transport material; and the lower functional layer of each emission structure may include a hole transport material.

In an embodiment, the upper functional layer of the upper emission structure may include multiple upper electron transport functional layers; the upper functional layer of the lower emission structure may include multiple lower electron transport functional layers; and three or more layers selected from the upper electron transport functional layers, the lower electron transport functional layers, and the n-type charge generation layer directly disposed on the lower emission structure may each independently include an electron transport material including a monocyclic 6-membered heteroaryl group that includes N as a ring-forming atom.

In an embodiment, the electron transport material that is included in at least one layer among the selected three or more layers may include a monocyclic 6-membered heteroaryl group that includes N as a ring-forming atom and a condensed ring that includes eight or more ring-forming carbon atoms.

In an embodiment, the electron transport material may be a compound selected from Compound Group 1, which is explained below.

According to an embodiment, an electronic device may include: a red light-emitting region, a green light-emitting region, and a blue light-emitting region that are separated from each other in a plan view; a circuit layer disposed on a base layer; and a display layer disposed on the circuit layer, wherein
the display layer may include a red light-emitting element disposed in the red light-emitting region, a green light-emitting element disposed in the green light-emitting region, and a blue light-emitting element disposed in the blue light-emitting region,
the red light-emitting element, the green light-emitting element, and the blue light-emitting element may each include: a first electrode; a second electrode facing the first electrode; a lower emission structure disposed between the first electrode and the second electrode, the lower emission structure including a first lower functional layer, a first emission layer, and a first upper functional layer that are sequentially stacked; an upper emission structure disposed on the lower emission structure, the upper emission structure including a second lower functional layer, a second emission layer, and a second upper functional layer that are sequentially stacked; and a charge generation layer disposed between the lower emission structure and the upper emission structure, the charge generation layer including an n-type charge generation layer and a p-type charge generation layer, and
the electronic device may satisfy Expression 1:

$$50 nm \geq {d}_{TOP} > {d}_{LOW} > 15 nm . \qquad [ Expression 1 ]$$

In Expression 1, d_{LOW} may be a sum of a thickness of the first upper functional layer and a thickness of the n-type charge generation layer; and d_{TOP} may be a thickness of the second upper functional layer.

In an embodiment, the first upper functional layer may include a first electron transport layer directly disposed under the n-type charge generation layer, and a first electron transport auxiliary layer directly disposed under the first electron transport layer; the second upper functional layer may include a second electron transport auxiliary layer directly disposed on the second emission layer, and a second electron transport layer directly disposed on the second electron transport auxiliary layer; and three or more layers selected from the first electron transport layer, the first electron transport auxiliary layer, the n-type charge generation layer, the second electron transport auxiliary layer, and the second electron transport layer may each independently include an electron transport material including a monocyclic 6-membered heteroaryl group that includes N as a ring-forming atom.

In an embodiment, the electron transport material that is included in at least one layer among the selected three or more layers may include a monocyclic 6-membered heteroaryl group that includes N as a ring-forming atom and a condensed ring that includes eight or more ring-forming carbon atoms.

In an embodiment, the first lower functional layer, the first upper functional layer, the charge generation layer, the second lower functional layer, and the second upper functional layer may each be disposed as a common layer in the red light-emitting region, the green light-emitting region, and the blue light-emitting region.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of the specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view of a display device according to an embodiment, taken along virtual line I-I′ of FIG. 1;

FIG. 3 is a schematic cross-sectional view of a display device according to an embodiment, taken along virtual line II-II′ of FIG. 1;

FIG. 4 is a schematic cross-sectional view of a light-emitting element according to an embodiment;

FIG. 5 is a schematic cross-sectional view of a light-emitting element according to an embodiment;

FIG. 6 is a schematic cross-sectional view of a light-emitting element according to an embodiment; and

FIG. 7 is a schematic cross-sectional view of a portion of a display panel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a light-emitting element according to an embodiment and a display device including the same will be described with reference to the drawings.

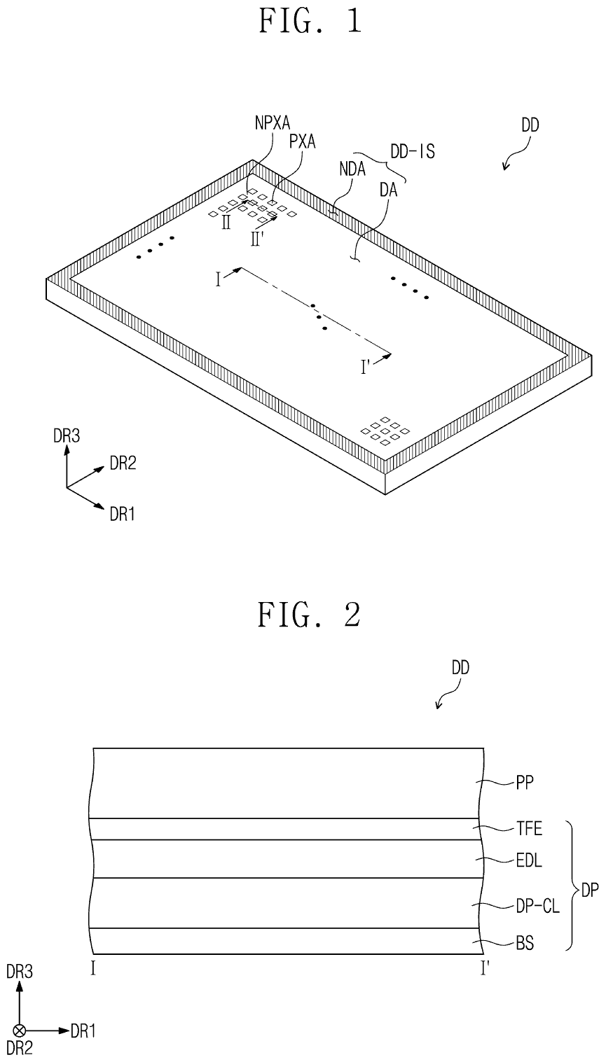

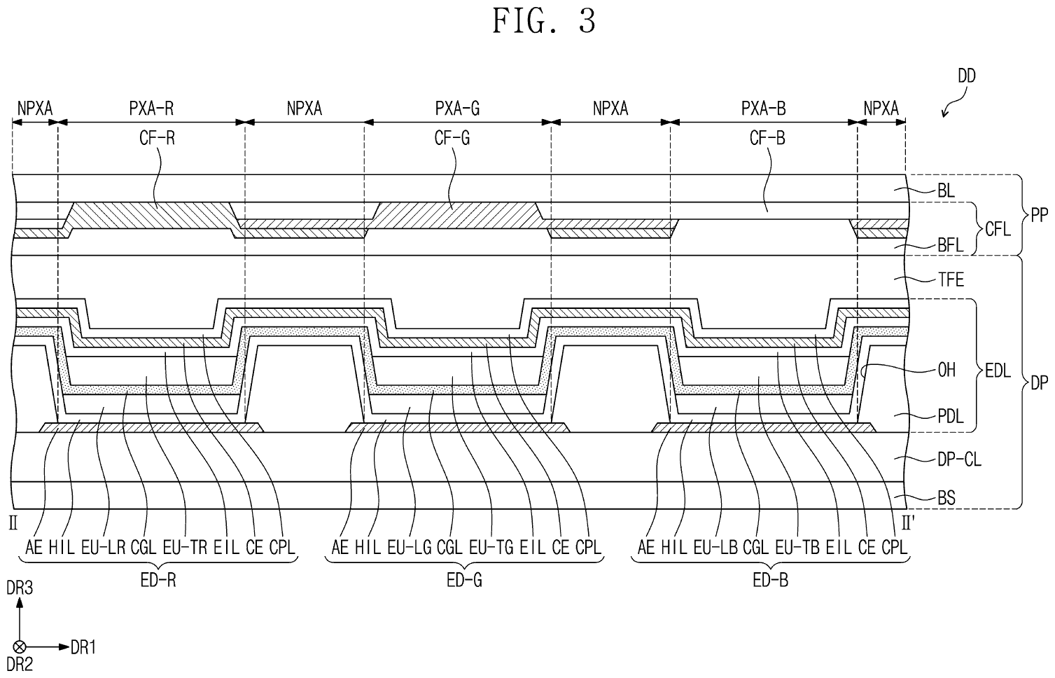

FIG. 1 is a schematic perspective view of a display device according to an embodiment. FIG. 2 is a schematic cross-sectional view of a display device according to an embodiment. FIG. 3 is a schematic cross-sectional view of a display device according to an embodiment. FIG. 2 is a schematic cross-sectional view taken along virtual line I-I′ of FIG. 1, and FIG. 3 is a schematic cross-sectional view taken along virtual line II-II′ of FIG. 1.

An electronic device according to an embodiment may be activated by an electrical signal. An electronic device may include a display device DD according to an embodiment. Examples of an electronic device may include a large device such as a television, a monitor, and a billboard. Further examples of an electronic device may include small and medium-sized devices such as a personal computer, a laptop computer, a personal digital assistant, a navigation unit, a game console, a smartphone, a tablet computer, and a camera. However, these are merely presented as examples, and the electronic device may also be included in other electronic devices.

The display device DD may display an image (or a video) through a display surface DD-IS. The display device DD may include light-emitting regions PXA and a non-light-emitting region NPXA. The display surface DD-IS may be parallel to a plane that is defined by a first direction DR1 and a second direction DR2. The display surface DD-IS may include a display region DA and a non-display region NDA. The light-emitting regions PXA may be disposed in the display region DA. The light-emitting regions PXA may be referred to as pixel regions.

The non-display region NDA may be defined along an edge of the display surface DD-IS. The non-display region NDA may surround the display region DA. However, embodiments are not limited thereto, and the non-display region NDA may be omitted, or the non-display region NDA may be disposed only on one side of the display region DA.

FIG. 1 shows that the display device DD has a display surface DD-IS that is flat, but embodiments are not limited thereto. For example, in embodiments, the display surface DD-IS of the display device DD may be a curved display surface or a three-dimensional display surface. The three-dimensional display surface may include multiple display regions that are disposed in different directions.

In FIGS. 1 to 7, a first direction axis DR1, a second direction axis DR2, and/or a third direction axis DR3 are illustrated. However, the directions indicated by the first to third direction axes DR1, DR2, and DR3 described in the specification are relative terms, and may be changed into other directions. The directions indicated by the first to third direction axes DR1, DR2, and DR3 may be respectively described as first to third directions, and may be denoted by the same reference numbers or symbols. In the specification, the first direction axis DR1 and the second direction axis DR2 may be perpendicular to each other, and the third direction axis DR3 may be a normal direction of a plane that is defined by the first direction axis DR1 and the second direction axis DR2. In the specification, a “plan view” may refer to a plane that is defined by the first direction axis DR1 and the second direction axis DR2, and a “cross-sectional view” may refer to a plane that is perpendicular to the plane that is defined by the first direction axis DR1 and the second direction axis DR2 and is parallel to the third direction axis DR3. A thickness direction of the display device DD may be a direction that is parallel to the third direction DR3, which is a normal direction of the plane that is defined by the first direction DR1 and the second direction DR2.

In the specification, upper surfaces (or front surfaces) and lower surfaces (or rear surfaces) of the members that constitute the display device DD may be defined with respect to the third direction DR3. For example, among two surfaces that face each other with respect to the third direction DR3, a surface that is relatively closer to the display surface DD-IS may be defined as a front surface (or an upper surface), and a surface that is relatively farther from the display surface DD-IS may be defined as a rear surface (or a lower surface). In the specification, an upper portion (or an upper side) and a lower portion (or a lower side) may be defined with respect to the third direction DR3, an upper portion (or an upper side) may be defined on the basis that it is relatively closer to the display surface DD-IS, and a lower portion (or a lower side) may be defined on the basis that it is relatively farther from the display surface DD-IS.

Referring to FIGS. 2 and 3, the display device DD may include a display panel DP, and an optical member PP disposed on the display panel DP. The display panel DP may include a display layer EDL. The display panel DP may include a base layer BS, a circuit layer DP-CL disposed on the base layer BS, and the display layer EDL disposed on the circuit layer DP-CL. The display layer EDL may include light-emitting elements ED-R, ED-G, and ED-B. The display panel DP may further include an encapsulation layer TFE disposed on the display layer EDL. The encapsulation layer TFE may be directly disposed on the display layer EDL, or an additional member may be disposed between the display layer EDL and the encapsulation layer TFE.

The display panel DP may be a component that generates an image. In the display device DD, the display panel DP may be a light-emitting display panel. In an embodiment, the display panel DP may be an organic light-emitting display panel that include an organic light-emitting element.

The optical member PP may be disposed on the display panel DP and may control light that is reflected at the display panel DP from an external light.

Referring to FIGS. 1 and 3, the light-emitting regions PXA may be disposed in the display region DA of the display device DD. The light-emitting regions PXA may be regions that emit light respectively generated by light-emitting elements ED-R, ED-G, and ED-B.

The light-emitting regions PXA in the display device DD according to an embodiment may be arranged in a stripe configuration. Referring to FIG. 1, the light-emitting regions PXA may be aligned along the first direction axis DR1 or the second direction axis DR2. However, embodiments are not limited thereto. For example, the light-emitting regions PXA may be arranged in a PenTile® configuration or in a Diamond Pixel® configuration.

FIGS. 1 and 3 illustrate that the light-emitting regions PXA all have a similar area. However, embodiments are not limited thereto, and the light-emitting regions PXA may be different in size or shape from each other, according to a wavelength range of emitted light.

The light-emitting regions PXA may include a first light-emitting region PXA-R, a second light-emitting region PXA-G, and a third light-emitting region PXA-B. The display device DD may include multiples of the light-emitting regions PXA-R, PXA-G, and PXA-B that are repeatedly disposed throughout the display region DA. The display device DD may include the first to third light-emitting regions PXA-R, PXA-G, and PXA-B that are separated from each other. The display device DD may include the non-light-emitting region NPXA that is disposed around and between the first to third light-emitting regions PXA-R, PXA-G, and PXA-B. The non-light-emitting region NPXA defines boundaries of the first to third light-emitting regions PXA-R, PXA-G, and PXA-B. The non-light-emitting region NPXA may surround the first to third light-emitting regions PXA-R, PXA-G, and PXA-B. A structure that prevents color mixing between the first to third light-emitting regions PXA-R, PXA-G, and PXA-B, for example, a pixel-defining layer PDL, etc., may be disposed in the non-light-emitting region NPXA. The first to third light-emitting regions PXA-R, PXA-G, and PXA-B may be spaced apart from each other in a plan view.

The first to third light-emitting regions PXA-R, PXA-G, and PXA-B may be regions that are separated from each other by the pixel-defining layer PDL. The non-light-emitting regions NPXA may be regions between the adjacent first to third light-emitting regions PXA-R, PXA-G, and PXA-B, and which may correspond to the pixel-defining layer PDL.

The first to third light-emitting regions PXA-R, PXA-G, and PXA-B may each be a region that emits light respectively generated by the first to third light-emitting elements ED-R, ED-G, and ED-B. The first to third light-emitting regions PXA-R, PXA-G, and PXA-B may be spaced apart from each other in a plan view.

In the specification, the first to third light-emitting regions PXA-R, PXA-G, and PXA-B may each correspond to a pixel. The pixel-defining layer PDL may separate the first to third light-emitting elements ED-R, ED-G, and ED-B. Emission structures EU-LR, EU-TR, EU-LG, EU-TG, EU-LB, and EU-TB of the first to third light-emitting elements ED-R, ED-G, and ED-B may be disposed in openings OH defined in the pixel-defining layer PDL and separated from each other.

The pixel-defining layer PDL may be formed of a polymer resin. For example, the pixel-defining layer PDL may include a polyacrylate-based resin or a polyimide-based resin. In an embodiment, the pixel-defining layer PDL may further include an inorganic material, in addition to a polymer resin. The pixel-defining layer PDL may further include a light absorbing material or may further include a black pigment or a black dye. When the pixel-defining layer PDL includes a black pigment or black dye, the pixel-defining layer PDL may be a black pixel-defining layer. When forming the pixel-defining layer PDL, carbon black, etc. may be used as a black pigment or black dye, but embodiments are not limited thereto.

In an embodiment, the pixel-defining layer PDL may include an inorganic material. For example, the pixel-defining layer PDL may include an inorganic material such as silicon nitride (SiNₓ), silicon oxide (SiOₓ), or silicon oxynitride (SiOₓN_{y}).

The first to third light-emitting regions PXA-R, PXA-G, and PXA-B may be arranged according to a color of light generated from the first to third light-emitting elements ED-R, ED-G, and ED-B. As an example, FIG. 3 illustrates three light-emitting regions PXA-R, PXA-G, and PXA-B that respectively emit red light, green light, and blue light in the display device DD. For example, in the display device DD according to an embodiment, the first light-emitting region PXA-R may correspond to a red light-emitting region, the second light-emitting region PXA-G may correspond to a green light-emitting region, and the third light-emitting region PXA-B may correspond to a blue light-emitting region.

In the display device DD according to an embodiment, the light-emitting elements ED-R, ED-G, and ED-B may emit light in different wavelength regions from each other. For example, in an embodiment, the first light-emitting element ED-R may be a red light-emitting element that emits red light, the second light-emitting element ED-G may be a green light-emitting element that emits green light, and the third light-emitting element ED-B may be a blue light-emitting element that emits blue light. For example, the red light-emitting region PXA-R, the green light-emitting region PXA-G, and the blue light-emitting region PXA-B of the display device DD may respectively correspond to the first light-emitting element ED-R, the second light-emitting element ED-G, and the third light-emitting element ED-B.

FIG. 3 illustrates three light-emitting regions PXA-R, PXA-G, and PXA-B that are separated from each other, but embodiments are not limited thereto, and the display device DD may include four or more light-emitting regions, each having different light emission characteristics.

In the display panel DP, the base layer BS may provide a base surface on which the display layer EDL is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not illustrated). The transistors (not illustrated) may each include a control electrode, an input electrode, and an output electrode. For example, the circuit layer DP-CL may include a switching transistor and a driving transistor for driving the light-emitting elements ED-R, ED-G, and ED-B of the display layer EDL.

The encapsulation layer TFE may cover the light-emitting elements ED-R, ED-G, and ED-B. The encapsulation layer TFE may encapsulate the display layer EDL. The encapsulation layer TFE may be a thin-film encapsulation layer. The encapsulation layer TFE may consist of a single layer or may include a stack of layers. The encapsulation layer TFE may include at least one insulating layer. The encapsulation layer TFE according to an embodiment may include at least one inorganic film (hereinafter, an inorganic encapsulation film). In an embodiment, the encapsulation layer TFE may include at least one organic film (hereinafter, an organic encapsulation film) and at least one inorganic encapsulation film.

The inorganic encapsulation film protects the display layer EDL from moisture and/or oxygen, and the organic encapsulation film protects the display layer EDL from foreign substances such as dust particles. The inorganic encapsulation film may include silicon nitride, silicon oxynitride, silicon oxide, titanium oxide, aluminum oxide, or the like, but embodiments are not limited thereto. The organic encapsulation film may include an acrylic compound, an epoxy-based compound, etc. The organic encapsulation film may include a photopolymerizable organic material, but embodiments are not limited thereto.

The optical member PP may be a glare reduction layer that reduces reflectance of an external light. For example, the optical member PP may include a polarizing film including a phase retarder and/or a polarizer, multiple reflective layers that cause destructive interference of reflected light, or color filters that are disposed to correspond to an arrangement and to a color of light emitted from a pixel of the display panel DP. If the optical member PP includes color filters, the color filters may be arranged in consideration of colors of light emitted from pixels that are included in the display panel DP. In an embodiment, the optical member PP may be omitted.

In an embodiment, the optical member PP may include a base substrate BL and a color filter layer CFL.

The base substrate BL may provide a base surface on which the color filter layer CFL, etc. are disposed. The base substrate BL may be a glass substrate, a metal substrate, a plastic substrate, etc. However, embodiments are not limited thereto, and the base substrate BL may include an inorganic layer, an organic layer, or a composite material layer.

The color filter layer CFL may include filters CF-R, CF-G, and CF-B. The color filter layer CFL may include a first filter CF-R, a second filter CF-G, and a third filter CF-B. The first to third filters CF-R, CF-G, and CF-B may be disposed to respectively correspond to the first to third light-emitting elements ED-R, ED-G, and ED-B. For example, the first filter CF-R may be a red filter, the second filter CF-G may be a green filter, and the third filter CF-B may be a blue filter. The first to third filters CF-R, CF-G, and CF-B may be disposed so that they respectively correspond to first to third light-emitting regions PXA-R, PXA-G, and PXA-B.

The filters CF-R, CF-G, and CF-B, each transmitting a different color of light, may be disposed to overlap the non-light-emitting region NPXA disposed between the light-emitting regions PXA-R, PXA-G, and PXA-B. The filters CF-R, CF-G, and CF-B may be disposed so that they overlap in a third direction DR3, which is a thickness direction, and so that they define boundaries between adjacent light-emitting regions PXA-R, PXA-G, and PXA-B. Accordingly, an external light blocking effect may increase, thus providing a same function as a black matrix. A structure of overlapping filters CF-R, CF-G, and CF-B may have a function of preventing color mixing.

The first to third filters CF-R, CF-G, and CF-B may each include a polymeric photosensitive resin, and a pigment or a dye. The first filter CF-R may include a red pigment or red dye, the second filter CF-G may include a green pigment or green dye, and the third filter CF-B may include a blue pigment or blue dye. However, embodiments are not limited thereto, and the third filter CF-B may not include a pigment or a dye. The third filter CF-B may include a polymeric photosensitive resin and may not include a pigment or a dye. The third filter CF-B may be transparent. The third filter CF-B may be formed of a transparent photosensitive resin.

The color filter layer CFL may further include a buffer layer BFL. For example, the buffer layer BFL may serve as a protective layer that protects the first to third filters CF-R, CF-G, and CF-B. The buffer layer BFL may be an inorganic material layer that includes at least one of silicon nitride, silicon oxide, and silicon oxynitride. The buffer layer BFL may have a single-layered structure or a multilayered structure.

In an embodiment, the first filter CF-R and the second filter CF-G may each be a yellow filter. The first filter CF-R and the second filter CF-G may not be provided as separate filters and may be provided as a unitary filter.

Although not shown in the drawings, the color filter layer CFL may further include a light blocking part (not illustrated). The light blocking part (not illustrated) may be a black matrix. The light blocking part (not illustrated) may include an inorganic light blocking material or an organic light blocking material, each including a black pigment or a black dye. The light blocking part (not illustrated) may prevent light leakage and may define boundaries between adjacent filters CF-R, CF-G, and CF-B.

Although not shown in the drawings, in an embodiment, the optical member PP may not include the color filter layer CFL.

In the display device DD according to an embodiment, the first to third light-emitting elements ED-R, ED-G, and ED-B may each include: a first electrode AE; a lower emission structure EU-LR, EU-LG, or EU-LB; a charge generation layer CGL; an upper emission structure EU-TR, EU-TG, or EU-TB; and a second electrode CE. FIG. 3 illustrates that the light-emitting elements ED-R, ED-G, and ED-B each include two emission structures stacked in the third direction DR3, which is a thickness direction, but embodiments are not limited thereto. For example, the light-emitting elements ED-R, ED-G, and ED-B may each include three or more emission structures disposed between the first electrode AE and the second electrode CE that are stacked in a thickness direction. When the light-emitting elements ED-R, ED-G, and ED-B include three or more emission structures, the light-emitting elements ED-R, ED-G, and ED-B may further include multiple charge generation layers, each disposed between adjacent emission structures among the three or more emission structures.

In an embodiment, the light-emitting elements ED-R, ED-G, and ED-B may include at least one emission layer in each of the lower emission structures EU-LR, EU-LG, and EU-LB and in each of the upper emission structures EU-TR, EU-TG, and EU-TB. For example, the light-emitting elements ED-R, ED-G, and ED-B may each be a light-emitting element having a tandem structure that includes multiple emission layers stacked in a thickness direction.

In an embodiment, the lower emission structures EU-LR, EU-LG, and EU-LB and the upper emission structures EU-TR, EU-TG, and EU-TB respectively included in the first to third light-emitting elements ED-R, ED-G, and ED-B may emit light having a same color. In an embodiment, the lower emission structures EU-LR, EU-LG, and EU-LB and the upper emission structures EU-TR, EU-TG, and EU-TB respectively included in the first to third light-emitting elements ED-R, ED-G, and ED-B may emit light in a same wavelength region. For example, the first light-emitting element ED-R may include the lower emissions structure EU-LR and the upper emission structure EU-TR that each emit light in a red light wavelength region, the second light-emitting element ED-G may include the lower emission structure EU-LG and the upper emission structure EU-TG that each emit light in a green light wavelength region, and the third light-emitting element ED-B may include the lower emission structure EU-LB and the upper emission structure EU-TB that each emit light in a blue light wavelength region. In the specification, the emission of light in a same wavelength region by emission structures stacked in a thickness direction in each light-emitting element may be interpreted to mean emission of light in wavelength regions in which the light is recognized as having a same color, even if the light emission wavelengths do not exactly match each other.

The emission structures and the charge generation layer included in the light-emitting elements ED-R, ED-G, and ED-B will be described in detail later. The light-emitting elements ED-R, ED-G, and ED-B may further include a capping layer CPL disposed on the second electrode CE. In an embodiment, the light-emitting elements ED-R, ED-G, and ED-B may further include at least one of a hole injection layer HIL disposed between the first electrode AE and an emission structure and an electron injection layer EIL disposed between an emission structure and the second electrode CE, in addition to the emission structure.

In an embodiment, at least a portion of the first electrode AE may be exposed in the opening OH defined in the pixel-defining layer PDL. The first electrode AE has conductivity. The first electrode AE may be formed of a metal material, a metal alloy, or a conductive compound. The first electrode AE may be an anode or a cathode. In an embodiment, the first electrode AE may be a pixel electrode. However, embodiments are not limited thereto.

The second electrode CE may be disposed on the first electrode AE. The second electrode CE may be a cathode or an anode. In an embodiment, when the first electrode AE is an anode, the second electrode CE may be a cathode, and when the first electrode AE is a cathode, the second electrode CE may be an anode. The second electrode CE may be a common electrode. However, embodiments are not limited thereto.

The lower emission structures EU-LR, EU-LG, and EU-LB may be disposed between the first electrode AE and the charge generation layer CGL, and the upper emission structures EU-TR, EU-TG, and EU-TB may be disposed between the charge generation layer CGL and the second electrode CE.

FIG. 3 illustrates that the lower emission structures EU-LR, EU-LG, and EU-LB and the upper emission structures EU-TR, EU-TG, and EU-TB of first to third light-emitting elements ED-R, ED-G, and ED-B are each entirely disposed in the openings OH. However, this is only an example. In an embodiment, in the lower emission structures EU-LR, EU-LG, and EU-LB and the upper emission structures EU-TR, EU-TG, and EU-TB, some components may be patterned and disposed in the openings OH, and other components may be provided as a common layer throughout the first to third light-emitting regions PXA-R, PXA-G, and PXA-B. In another embodiment, in the lower emission structures EU-LR, EU-LG, and EU-LB and the upper emission structures EU-TR, EU-TG, and EU-TB, at least some components may be provided by extending over the pixel-defining layer PDL, or at least some components may be connected with each other.

In the display device DD, the lower emission structures EU-LR, EU-LG, and EU-LB, the upper emission structures EU-TR, EU-TG, and EU-TB, and the like of the first to third light-emitting elements ED-R, ED-G, and ED-B may each be formed by being patterned using an inkjet printing method. However, embodiments are not limited thereto. The lower emission structures EU-LR, EU-LG, and EU-LB and the upper emission structures EU-TR, EU-TG, and EU-TB may be formed through a method other than an inkjet printing method.

In the display device DD, the second electrode CE and the capping layer CPL may each be provided as a common layer throughout the first to third light-emitting elements ED-R, ED-G, and ED-B. However, embodiments are not limited thereto, and at least one of the second electrode CE and the capping layer CPL may be provided by being patterned in the openings OH in each of the light-emitting regions PXA-R, PXA-G, and PXA-B.

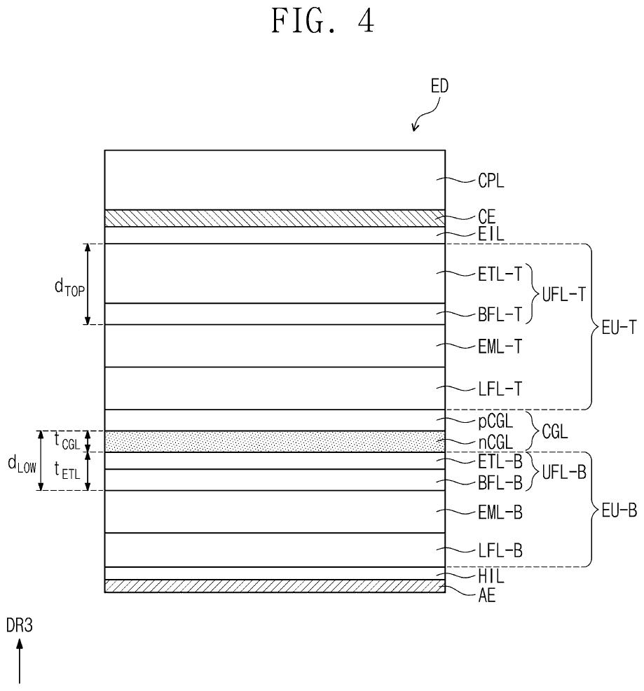

FIGS. 4 to 6 are each a schematic cross-sectional view of a light-emitting element according to an embodiment. FIGS. 4 to 6 each show a structure of a light-emitting element according to an embodiment. In embodiments, the first to third light-emitting elements ED-R, ED-G, and ED-B illustrated in FIG. 3 may each independently have a structure according to a light-emitting element ED, ED-a, or ED-1 as respectively illustrated in FIGS. 4 to 6.

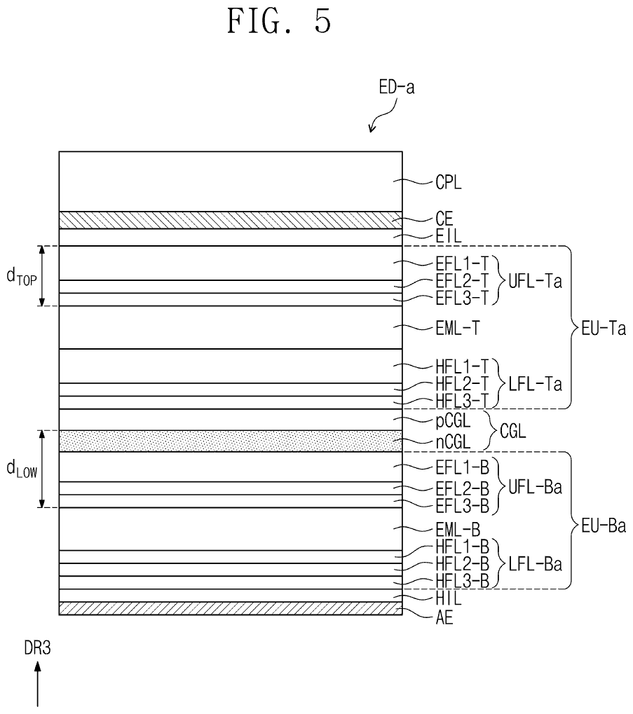

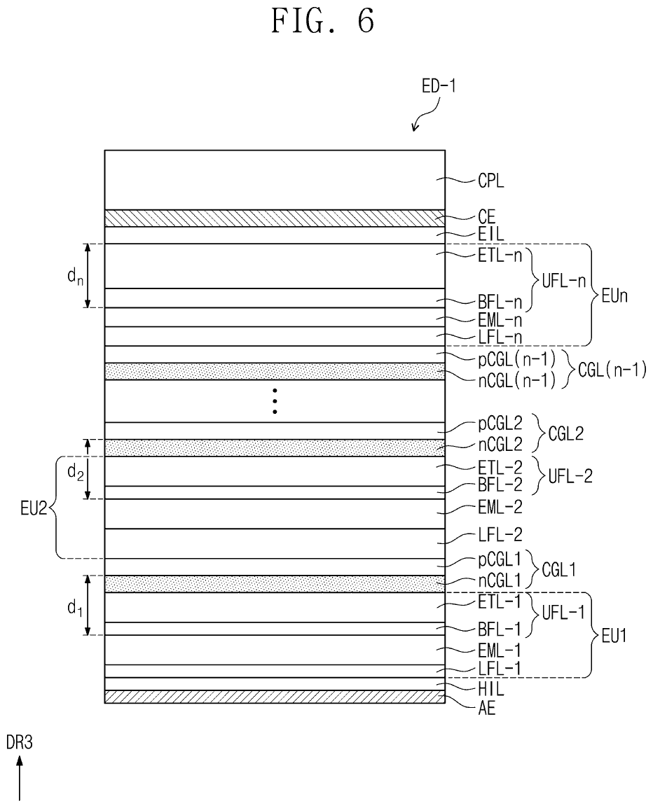

FIGS. 4 and 5 each illustrate an embodiment of a light-emitting element that includes two emission structures stacked between a first electrode AE and a second electrode CE. FIG. 6 illustrates an embodiment of a light-emitting element that includes three or more emission structures stacked between a first electrode AE and a second electrode CE.

According to an embodiment illustrated in FIG. 4, a light-emitting element ED may include a first electrode AE, a hole injection layer HIL, a lower emission structure EU-B, a charge generation layer CGL, an upper emission structure EU-T, an electron injection layer EIL, a second electrode CE, and a capping layer CPL, which are stacked in that order in a third direction DR3. According to an embodiment illustrated in FIG. 5, a light-emitting element ED-a may include a first electrode AE, a hole injection layer HIL, a lower emission structure EU-Ba, a charge generation layer CGL, an upper emission structure EU-Ta, an electron injection layer EIL, a second electrode CE, and a capping layer CPL, which are stacked in that order in a third direction DR3. The light-emitting element ED-a illustrated in FIG. 5 may differ from the light-emitting element ED illustrated in FIG. 4 at least in the configuration of sub functional layers included in lower functional layers LFL-B, LFL-Ba, LFL-T, and LFL-Ta and upper functional layers UFL-B, UFL-Ba, UFL-T, and UFL-Ta.

A light-emitting element ED-1 according to an embodiment illustrated in FIG. 6 may include n emission structures EU1, EU2, . . . , and EUn between the first electrode AE and the second electrode CE. The light-emitting element ED-1 may include the first electrode AE, a hole injection layer HIL, the n emission structures EU1, EU2, . . . , and EUn, (n−1) charge generation layer CGL1, CGL2, . . . , and CGL(n−1), an electron injection layer EIL, the second electrode CE, and a capping layer CPL. In the embodiment illustrated in FIG. 6, n may be an integer equal to or greater than 3. Each of the n emission structures EU1, EU2, . . . , and EUn may respectively include: lower functional layers LFL-1, LFL-2, . . . , and LFL-n; emission layers EML-1, EML-2, . . . , and EML-n; and upper functional layers UFL-1, UFL-2, . . . , and UFL-n. Each of the (n−1) charge generation layers CGL1, CGL2, . . . , and CGL(n−1) may respectively include: n-type charge generation layers nCGL1, nCGL2, . . . , and nCGL(n−1); and p-type charge generation layers pCGL1, pCGL2, . . . , and pCGL(n−1). Charge generation layers CGL1, CGL2, . . . , and CGL(n−1) may each be disposed between adjacent emission structures among the emission structures EU1, EU2, . . . , and EUn. For example, a first charge generation layer CGL1 may be disposed between a first emission structure EU1 and a second emission structure EU2, a second charge generation layer CGL2 may be disposed on the second emission structure EU2, and an (n−1)-th charge generation layer CGL(n−1) may be disposed under an n-th emission structure EUn.

In the light-emitting elements ED, ED-a, and ED-1 as respectively illustrated in FIGS. 4 to 6, the first electrode AE may be a transmissive electrode, a semi-transmissive electrode, or a reflective electrode. The first electrode AE may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

When the first electrode AE is a transmissive electrode, the first electrode AE may include a transparent metal oxide, e.g., indium tin oxide (ITO), indium zinc oxide (IZO), zinc oxide (ZnO), indium tin zinc oxide (ITZO), etc. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In an embodiment, the first electrode AE may have a multilayered structure that includes a reflective film or semi-transmissive film that is formed of the materials described above, and a transparent conductive film that is formed of indium tin oxide (ITO), indium zinc oxide (IZO), zinc oxide (ZnO), indium tin zinc oxide (ITZO), etc. For example, the first electrode AE may have a three-layered structure of ITO/Ag/ITO, but embodiments are not limited thereto. In embodiments, the first electrode AE may include a metal material as described above, a combination of two or more metal materials as described above, an oxide of a metal material as described above, or the like, but embodiments are not limited thereto. A thickness of the first electrode AE may be in a range of about 700 Å to about 10,000 Å. For example, a thickness of the first electrode AE may be in a range of about 1,000 Å to about 3,000 Å.

The second electrode CE may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

The second electrode CE may be a transmissive electrode, a semi-transmissive electrode, or a reflective electrode. When the second electrode CE is a transmissive electrode, the second electrode CE may include a transparent metal oxide, e.g., indium tin oxide (ITO), indium zinc oxide (IZO), zinc oxide (ZnO), indium tin zinc oxide (ITZO), etc.

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode CE may have a multilayered structure that includes a reflective film or semi-transmissive film that is formed of the materials described above, and a transparent conductive film that is formed of indium tin oxide (ITO), indium zinc oxide (IZO), zinc oxide (ZnO), indium tin zinc oxide (ITZO), etc. For example, the second electrode CE may include a metal material as described above, a combination of two or more metal materials as described above, an oxide of a metal materials as described above, or the like.

Although not shown in the drawings, the second electrode CE may be electrically connected to an auxiliary electrode (not illustrated). The auxiliary electrode (not illustrated) may be formed of a conductive pattern in the circuit layer DP-CL (FIG. 3). When the second electrode CE is electrically connected to the auxiliary electrode (not illustrated), resistance of the second electrode CE may be reduced.

The light-emitting elements ED, ED-a, and ED-1 of embodiments may include a capping layer CPL disposed on the second electrode CE. The capping layer CPL may have a multilayered structure or a single-layered structure.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra (biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

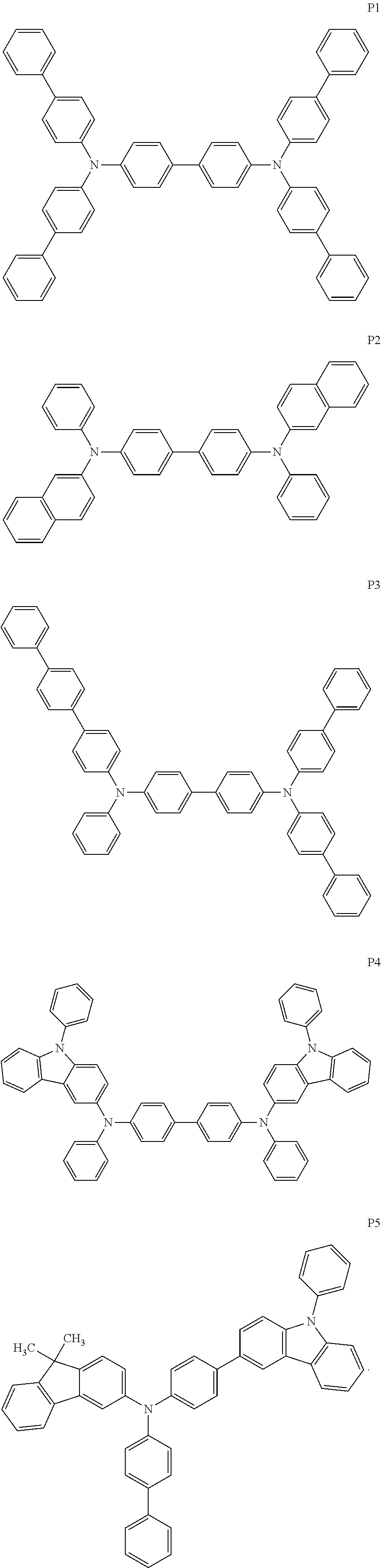 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6, with respect to light in a wavelength range of about 550 nm to about 660 nm. In an embodiment, in the light-emitting elements ED, ED-a, and ED-1, the capping layer CPL may be omitted.

Referring to the light-emitting element ED shown in FIG. 4, the lower emission structure EU-B may include a first lower functional layer LFL-B, a first emission layer EML-B, and a first upper functional layer UFL-B, which are stacked in that order from the first electrode AE, and the upper emission structure EU-T may include a second lower functional layer LFL-T, a second emission layer EML-T, and a second upper functional layer UFL-T, which are stacked in that order from the charge generation layer CGL.

Referring to the light-emitting element ED-a shown in FIG. 5, the lower emission structure EU-Ba may include a first lower functional layer LFL-Ba, a first emission layer EML-B, and a first upper functional layer UFL-Ba, which are stacked in that order from the first electrode AE, and the upper emission structure EU-Ta may include a second lower functional layer LFL-Ta, a second emission layer EML-T, and a second upper functional layer UFL-Ta, which are stacked in that order from the charge generation layer CGL.

In FIGS. 4 and 5, the upper functional layers UFL-B, UFL-T, UFL-Ba, and UFL-Ta may each be an electron transport functional layer that performs an electron injection function or an electron transport function; and the lower functional layers LFL-B, LFL-Ba, LFL-T, and LFL-Ta may each be a hole transport functional layer that performs a hole injection function or a hole transport function.

In FIGS. 4 and 5, the upper functional layers UFL-B, UFL-T, UFL-Ba, and UFL-Ta may each have a multilayered structure having multiple layers. The upper functional layers UFL-B, UFL-T, UFL-Ba, and UFL-Ta may each have a multilayered structure having multiple layers that include different materials. In embodiments, the upper functional layers UFL-B, UFL-T, UFL-Ba, and UFL-Ta may each independently have an electron transport layer/an electron injection layer structure, a buffer layer/an electron transport layer structure, a hole blocking layer/an electron transport layer/an electron injection layer structure, etc., in which the layers of each structure are stacked in its respective stated order from the emission layers EML-B and EML-T, but embodiments are not limited thereto. In the specification, a buffer layer may be referred to as an electron transport layer or an auxiliary electron transport layer. The buffer layer may perform a supplementary electron transport function. The hole blocking layer may prevent hole injection to an electron transport functional layer from hole transport functional layers.

In FIGS. 4 and 5, the lower functional layers LFL-B, LFL-Ba, LFL-T, and LFL-Ta may each independently have a structure consisting of a layer consisting of a single material, a structure consisting of a layer including different materials, or a structure including multiple layers including different materials. For example, the lower functional layers LFL-B, LFL-Ba, LFL-T, and LFL-Ta may each have a single-layered structure of a hole injection layer or a hole transport layer or may each have a single-layered structure that includes a hole injection material and a hole transport material. In embodiments, the lower functional layers LFL-B, LFL-Ba, LFL-T, and LFL-Ta may each have a single-layered structure including different materials, or may each independently have a hole injection layer/a hole transport layer structure, a hole injection layer/a hole transport layer/an emission auxiliary layer structure, a hole injection layer/an emission auxiliary layer structure, a hole transport layer/an emission auxiliary layer structure, a hole injection layer/a hole transport layer/an emission auxiliary layer structure, a hole injection layer/a hole transport layer/an electron blocking layer structure, or the like, in which the layers of each structure are stacked in its respective stated order from the first electrode AE, but embodiments are not limited thereto.

The emission auxiliary layer may compensate for a resonance distance according to a wavelength of light emitted from the emission layers EML-B and EML-T, and may adjust hole charge balance, thereby increasing light emission efficiency. The emission auxiliary layer may include a hole transport material. The electron blocking layer may also prevent electron injection from the electron transport functional layers to a hole transport functional layer.

In the light-emitting element ED illustrated in FIG. 4, the first upper functional layer UFL-B may have a stacked structure of a first electron transport auxiliary layer BFL-B and a first electron transport layer ETL-B, and the second upper functional layer UFL-T may have a stacked structure of a second electron transport auxiliary layer BFL-T and a second electron transport layer ETL-T. In an embodiment, the first electron transport auxiliary layer BFL-B and the second electron transport auxiliary layer BFL-T may each independently perform a function of an electron transport layer, a buffer layer, or a hole blocking layer.

In the light-emitting element ED illustrated in FIG. 4, the first lower functional layer LFL-B and the second lower functional layer LFL-T may each have a single-layered structure. In FIG. 4, the first lower functional layer LFL-B may perform a function of a hole transport layer, and the second lower functional layer LFL-T may perform a function of an emission auxiliary layer.

In contrast to the light-emitting element ED illustrated in FIG. 4, in the light-emitting element ED-a illustrated in FIG. 5, the lower functional layers LFL-Ba and LFL-Ta and the upper functional layers UFL-Ba and UFL-Ta may each include three sub functional layers. The first lower functional layer LFL-Ba may include first to third lower sub functional layers HFL1-B, HFL2-B, and HFL3-B, and the first upper functional layer UFL-Ba may include first to third upper sub functional layers EFL1-B, EFL2-B, and EFL3-B. The second lower functional layer LFL-Ta may include fourth to sixth lower sub functional layers HFL1-T, HFL2-T, and HFL3-T, and the second upper functional layer UFL-Ta may include fourth to sixth upper sub functional layers EFL1-T, EFL2-T, and EFL3-T.

In the light-emitting element ED-a illustrated in FIG. 5, the first upper functional layer UFL-Ba may include the first upper sub functional layer EFL1-B, the second upper sub functional layer EFL2-B, and the third upper sub functional layer EFL3-B, which are disposed on the first emission layer EML-B and sequentially disposed in a direction from the charge generation layer CGL to the first emission layer EML-B. In an embodiment, the first to third upper sub functional layers EFL1-B, EFL2-B, and EFL3-B may each be an electron transport functional layer.

In an embodiment, the first upper sub functional layer EFL1-B may perform a function of an electron transport layer or an electron injection layer; and the second upper sub functional layer EFL2-B and the third upper sub functional layer EFL3-B may each independently perform a function of an electron transport layer, a buffer layer, or a hole blocking layer. For example, in an embodiment, the first upper sub functional layer EFL1-B may be an electron transport layer, the second upper sub functional layer EFL2-B may be a buffer layer, and the third upper sub functional layer EFL3-B may be a hole blocking layer. However, embodiments are not limited thereto.

In the light-emitting element ED-a illustrated in FIG. 5, the second upper functional layer UFL-Ta may include the fourth upper sub functional layer EFL1-T, the fifth upper sub functional layer EFL2-T, and the sixth upper sub functional layer EFL3-T, which are disposed on the second emission layer EML-T and sequentially disposed in a direction from the second electrode CE to the second emission layer EML-T. In an embodiment, the fourth to sixth upper sub functional layers EFL1-T, EFL2-T, and EFL3-T may each be an electron transport sub functional layer.

In an embodiment, the fourth upper sub functional layer EFL1-T may perform a function of an electron transport layer or an electron injection layer; and the fifth upper sub functional layer EFL2-T and the sixth upper sub functional layer EFL3-T may each independently perform a function of an electron transport layer, a buffer layer, or a hole blocking layer. For example, in an embodiment, the fourth upper sub functional layer EFL1-T may be an electron transport layer, the fifth upper sub functional layer EFL2-T may be a buffer layer, and the sixth upper sub functional layer EFL3-T may be a hole blocking layer. However, embodiments are not limited thereto.

In the light-emitting element ED-a illustrated in FIG. 5, the first lower functional layer LFL-Ba may include the first lower sub functional layer HFL1-B, the second lower sub functional layer HFL2-B, and the third lower sub functional layer HFL3-B, which are disposed under the first emission layer EML-B and sequentially disposed in a direction from the first emission layer EML-B to the first electrode AE. In an embodiment, the first to third lower sub functional layers HFL1-B, HFL2-B, and HFL3-B may each be a hole transport functional layer.

In an embodiment, the first lower sub functional layer HFL1-B and the second lower sub functional layer HFL2-B may each independently perform a function of a hole transport layer, an emission auxiliary layer, or an electron blocking layer; and the third lower sub functional layer HFL3-B may perform a function of a hole transport layer or a hole injection layer. For example, in an embodiment, the first lower sub functional layer HFL1-B may be an emission auxiliary layer or an electron blocking layer, the second lower sub functional layer HFL2-B may be a hole transport layer, and the third lower sub functional layer HFL3-B may be a hole transport layer or a hole injection layer. However, embodiments are not limited thereto.

In the light-emitting element ED-a illustrated in FIG. 5, the second lower functional layer LFL-Ta may include the fourth lower sub functional layer HFL1-T, the fifth lower sub functional layer HFL2-T, and the sixth lower sub functional layer HFL3-T, which are disposed under the second emission layer EML-T and sequentially disposed in a direction from the second emission layer EML-T to the charge generation layer CGL. In an embodiment, the fourth to sixth lower sub functional layers HFL1-T, HFL2-T, and HFL3-T may each be a hole transport functional layer.

In an embodiment, the fourth lower sub functional layer HFL1-T and the fifth lower sub functional layer HFL2-T may each independently perform a function of a hole transport layer, an emission auxiliary layer, or an electron blocking layer; and the sixth lower sub functional layer HFL3-T may perform a function of a hole transport layer or a hole injection layer. For example, in an embodiment, the fourth lower sub functional layer HFL1-T may be an emission auxiliary layer, an electron blocking layer, or a hole transport layer, the fifth lower sub functional layer HFL2-T may be a hole transport layer, and the sixth lower sub functional layer HFL3-T may be a hole transport layer or a hole injection layer. However, embodiments are not limited thereto.

Referring to FIGS. 4 and 5, the light-emitting elements ED and ED-a may each include the charge generation layer CGL disposed between the lower emission structures EU-B and EU-Ba and the upper emission structures EU-T and EU-Ta. The charge generation layer CGL may generate charges (electrons and holes) by forming a complex through an oxidation-reduction reaction when voltage is applied to the light-emitting elements ED and ED-a. The charge generation layer CGL may provide the generated charges to each of adjacent lower emission structures EU-B and EU-Ba and upper emission structures EU-T and EU-Ta. The charge generation layer CGL may increase efficiency of current generated in each of adjacent emission structures EU-B, EU-Ba, EU-T, and EU-Ta and may control a balance of charges between adjacent emission structures (EU-B and EU-T, and EU-Ba and EU-Ta). The charge generation layer CGL may include an n-type charge generation layer nCGL and a p-type charge generation layer pCGL. The charge generation layer CGL may have a structure in which the n-type charge generation layer nCGL and the p-type charge generation layer pCGL are bonded to each other.

The n-type charge generation layer nCGL may be a charge generation layer that provides electrons to adjacent emission structures EU-B and EU-Ba. The n-type charge generation layer nCGL may include a base material that is doped with an n-dopant. The p-type charge generation layer pCGL may be a charge generation layer that provides holes to adjacent emission structures EU-T and EU-Ta. The p-type charge generation layer pCGL may include a base material that is doped with a p-dopant. In an embodiment, the charge generation layer CGL may further include a buffer layer (not illustrated) disposed between the n-type charge generation layer nCGL and the p-type charge generation layer pCGL. For example, in an embodiment, the n-type charge generation layer nCGL may be an electron transport functional layer that performs an electron transport function, and the p-type charge generation layer pCGL may be a hole transport functional layer that performs a hole transport function.

According to embodiments, the light-emitting element ED illustrated in FIG. 4 may satisfy Expression 1:

$$50 nm \geq {d}_{TOP} > {d}_{LOW} > 15 nm \qquad [ Expression 1 ]$$

In Expression 1, d_{LOW} may be a sum of a thickness t_{ETL} of the first upper functional layer UFL-B and a thickness t_{CGL} of the n-type charge generation layer nCGL; and d_{TOP} may be a thickness of the second upper functional layer UFL-T.

Thus, in the light-emitting element ED, a thickness of the second upper functional layer UFL-T, which includes the second electron transport layer ETL-T and the second electron transport auxiliary layer BFL-T that performs an electron transport function in the upper emission structure EU-T, wherein the second upper functional layer UFL-T is disposed adjacent to the second electrode CE, may be greater than a sum of a thickness of the n-type charge generation layer nCGL, a thickness of the first electron transport layer ETL-B, and a thickness of the first electron transport auxiliary layer BFL-B that performs an electron transport function in the lower emission structure EU-B, wherein the n-type charge generation layer nCGL, the first electron transport layer ETL-B, and the first electron transport auxiliary layer BFL-B are disposed between the upper emission structure EU-T and the first electrode AE.

When the light-emitting element ED satisfies the thickness relationship of Expression 1, excitons may be effectively formed in each emission structure EU-B and EU-T, so that a movement distance of charges to an adjacent layer that is not an emission layer may be reduced. A thickness of an electron transport functional layer in the lower emission structure EU-B may be smaller than a thickness of an electron transport functional layer in the upper emission structure EU-T, and thus, an increase in driving voltage and overshoot may be suppressed, thereby facilitating low power consumption and improved driving lifespan. Accordingly, the light-emitting element ED may exhibit characteristics of excellent light emission efficiency and a long lifespan, and a display device that includes the light-emitting element ED may exhibit characteristics of excellent display quality and a long lifespan.

In the light-emitting element ED, the first upper functional layer UFL-B, the second upper functional layer UFL-T, and the n-type charge generation layer nCGL may each include an electron transport material, and the first lower functional layer LFL-B and the second lower functional layer LFL-T may each include a hole transport material.

The first upper functional layer UFL-B, the second upper functional layer UFL-T, and the n-type charge generation layer nCGL may each include at least one sub layer, and three or more layers selected from the sub layers included in the first upper functional layer UFL-B, the second upper functional layer UFL-T, and the n-type charge generation layer nCGL may each independently include an electron transport material including a monocyclic 6-membered heteroaryl group that includes N as a ring-forming atom. For example, three or more layers selected from the sub layers that perform an electron transport function may each independently include at least one monocyclic 6-membered heteroaryl group that includes N as a ring-forming atom. For example, the monocyclic 6-membered heteroaryl group that includes N as a ring-forming atom may be pyridine, pyrimidine, or triazine.

The first upper functional layer UFL-B, the second upper functional layer UFL-T, and the n-type charge generation layer nCGL may each include at least one sub layer, and at least one sub layer may include an electron transport material that includes a monocyclic 6-membered heteroaryl group that includes N as a ring-forming atom and a condensed ring that includes eight or more ring-forming carbon atoms. In an embodiment, among the sub layers included in the first upper functional layer UFL-B, the second upper functional layer UFL-T, and the n-type charge generation layer nCGL, three or more sub layers selected therefrom may each independently include an electron transport material including at least one monocyclic 6-membered heteroaryl group that includes N as a ring-forming atom; and among the selected three or more sub layers, the electron transport material included in at least one sub layer thereof may include: a monocyclic 6-membered heteroaryl group that includes N as a ring-forming atom; and a condensed ring that includes eight or more ring-forming carbon atoms.

In an embodiment, at least one of the electron transport materials included in the electron transport functional layers may be a compound including both a monocyclic 6-membered heteroaryl group that includes N as a ring-forming atom, and a condensed ring that includes eight or more ring-forming carbon atoms. In an embodiment, the condensed ring may be naphthalene, anthracene, fluorene, phenanthrene, spiro-bifluorene, fluoranthene, chrysene, quinoline, quinazoline, phenanthroline, dibenzofuran, or dibenzothiophene. However, embodiments are not limited thereto.

In an embodiment, the first upper functional layer UFL-B may include the first electron transport layer ETL-B directly disposed under the n-type charge generation layer nCGL and the first electron transport auxiliary layer BFL-B directly disposed under the first electron transport layer ETL-B; and the second upper functional layer UFL-T may include the second electron transport auxiliary layer BFL-T directly disposed on the second emission layer EML-T and the second electron transport layer ETL-T directly disposed on the second electron transport auxiliary layer BFL-T.

In the light-emitting element ED illustrated in FIG. 4, three or more layers selected from the first electron transport layer ETL-B, the first electron transport auxiliary layer BFL-B, the n-type charge generation layer nCGL, the second electron transport auxiliary layer BFL-T, and the second electron transport layer ETL-T may each independently include an electron transport material including a monocyclic 6-membered heteroaryl group that includes N as a ring-forming atom. In an embodiment, at least one layer among the selected three or more layers may include an electron transport material including both a monocyclic 6-membered heteroaryl group that includes N as a ring-forming atom and a condensed ring that includes eight or more ring-forming carbon atoms.

According to embodiments, the light-emitting element ED-a illustrated in FIG. 5 may also satisfy Expression 1:

$$50 nm \geq {d}_{TOP} > {d}_{LOW} > 15 nm \qquad [ Expression 1 ]$$

In Expression 1, d_{LOW} may be a sum of a thickness of the first upper functional layer UFL-Ba and a thickness of the n-type charge generation layer nCGL; and d_{TOP} may be a thickness of the second upper functional layer UFL-Ta. Thus, the light-emitting element ED-a illustrated in FIG. 5 may also satisfy the thickness relationship of Expression 1, in which the first upper functional layer UFL-Ba is an electron transport functional layer of the lower emission structure EU-Ba, the second upper functional layer UFL-Ta is an electron transport functional layer of the upper emission structure EU-Ta, and the first upper functional layer UFL-Ba and the second upper functional layer UFL-Ta each include three or more sub functional layers.

In the light-emitting element ED-a, a thickness of the second upper functional layer UFL-Ta, which includes the electron transport sub functional layers EFL1-T, EFL2-T, and EFL3-T that perform an electron transport function in the upper emission structure EU-Ta, wherein the upper emission structure EU-Ta is disposed adjacent to the second electrode CE, may be greater than a sum of a thickness of each of the n-type charge generation layer nCGL and the electron transport sub functional layers EFL1-B, EFL2-B, and EFL3-B that perform an electron transport function in the lower emission structure EU-Ba, wherein the n-type charge generation layer nCGL and electron transport sub functional layers EFL1-B, EFL2-B, and EFL3-B are disposed between the upper emission structure EU-Ta and the first electrode AE.

When the light-emitting element ED-a satisfies the thickness relationship of Expression 1, excitons may be effectively formed in each emission structure EU-Ba and EU-Ta, so that a movement distance of charges to an adjacent layer that is not an emission layer may be reduced. Accordingly, the light-emitting element ED-a may exhibit characteristics of excellent light emission efficiency and a long lifespan. A thickness of an electron transport functional layer in the lower emission structure EU-Ba may be smaller than a thickness of an electron transport functional layer in the upper emission structure EU-Ta, and thus, an increase in driving voltage and overshoot may be suppressed, thereby facilitating low power consumption and improved driving lifespan. Accordingly, the light-emitting element ED-a may exhibit characteristics of excellent light emission efficiency and a long lifespan, and a display device that includes the light-emitting element ED-a may exhibit characteristics of excellent display quality and a long lifespan.

The first upper functional layer UFL-Ba, the second upper functional layer UFL-Ta, and the n-type charge generation layer nCGL may each include at least one sub layer, and three or more layers selected from the sub layers included in the first upper functional layer UFL-Ba, the second upper functional layer UFL-Ta, and the n-type charge generation layer nCGL may each independently include an electron transport material including a monocyclic 6-membered heteroaryl group that includes N as a ring-forming atom. For example, in the light-emitting element ED-a illustrated in FIG. 5, three or more layers selected from the n-type charge generation layer nCGL and the electron transport sub functional layers EFL1-B, EFL2-B, EFL3-B, EFL1-T, EFL2-T, and EFL3-T that perform an electron transport function may each independently include at least one monocyclic 6-membered heteroaryl group that includes N as a ring-forming atom. For example, the monocyclic 6-membered heteroaryl group that includes N as a ring-forming atom may be pyridine, pyrimidine, or triazine.

In an embodiment, at least one layer among the first to third upper sub functional layers EFL1-B, EFL2-B, and EFL3-B, the fourth to sixth upper sub functional layers EFL1-T, EFL2-T, and EFL3-T, which are electron transport sub functional layers, and the n-type charge generation layer nCGL may each independently include an electron transport material including a monocyclic 6-membered heteroaryl group that includes N as a ring-forming atom, and a condensed ring that includes eight or more ring-forming carbon atoms. In an embodiment, among the sub functional layers included in the first upper functional layer UFL-Ba, the second upper functional layer UFL-Ta, and the n-type charge generation layer nCGL, three or more sub functional layers selected therefrom may each independently include an electron transport material including at least one monocyclic 6-membered heteroaryl group that includes N as a ring-forming atom; and among the selected three or more sub functional layers, the electron transport material included in at least one sub functional layer thereof may include: a monocyclic 6-membered heteroaryl group that includes N as a ring-forming atom; and a condensed ring that includes eight or more ring-forming carbon atoms.

In an embodiment, at least one of the electron transport materials included in the electron transport sub functional layers may be a compound including both a monocyclic 6-membered heteroaryl group that includes N as a ring-forming atom, and a condensed ring that includes eight or more ring-forming carbon atoms. In an embodiment, the condensed ring may be naphthalene, anthracene, fluorene, phenanthrene, spiro-bifluorene, fluoranthene, chrysene, quinoline, quinazoline, phenanthroline, dibenzofuran, or dibenzothiophene. However, embodiments are not limited thereto.

In an embodiment, in the light-emitting elements ED and ED-a respectively illustrated in FIGS. 4 and 5, an electron transport material included in at least one of the first upper functional layers UFL-B and UFL-Ba, the second upper functional layers UFL-T and UFL-Ta, and the n-type charge generation layer nCGL may each independently be a compound selected from Compound Group 1. The compounds listed in Compound Group 1 may each include a monocyclic 6-membered heteroaryl group that includes N as a ring-forming atom. In Compound Group 1, Compounds 13 to 58 may each include a monocyclic 6-membered heteroaryl group that includes N as a ring-forming atom, and a condensed ring that includes eight or more ring-forming carbon atoms.

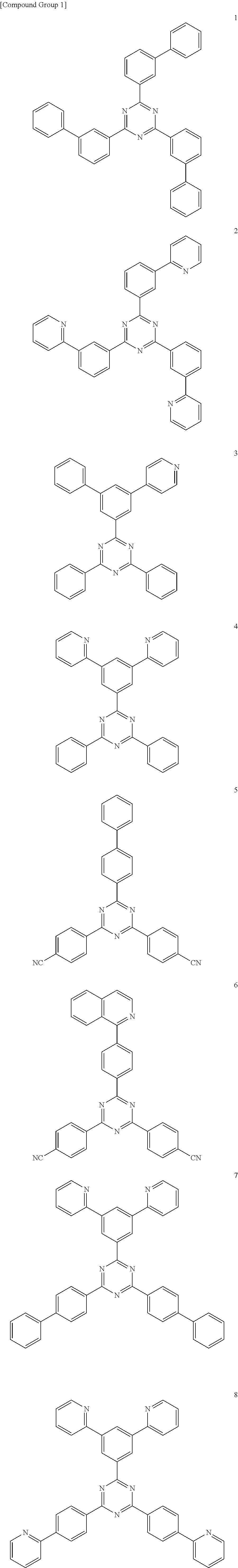

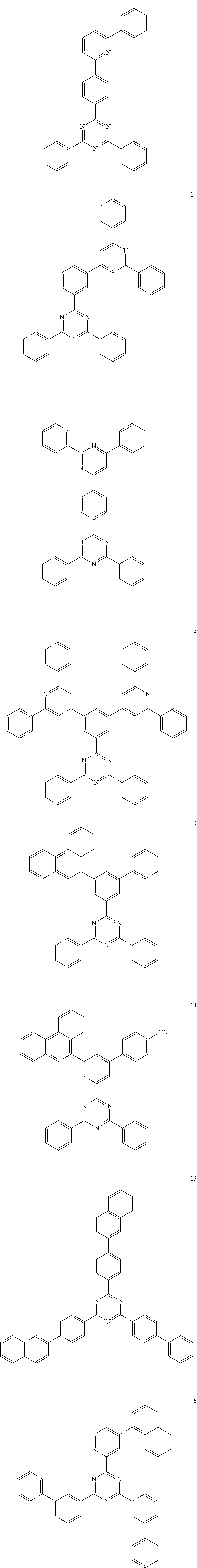

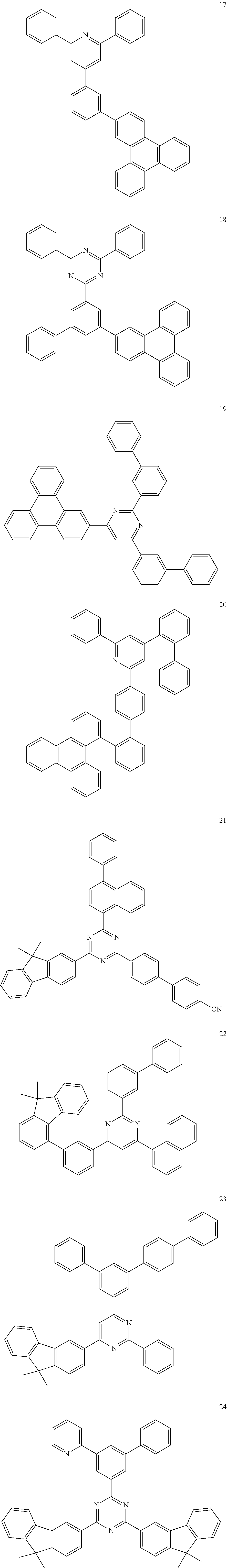

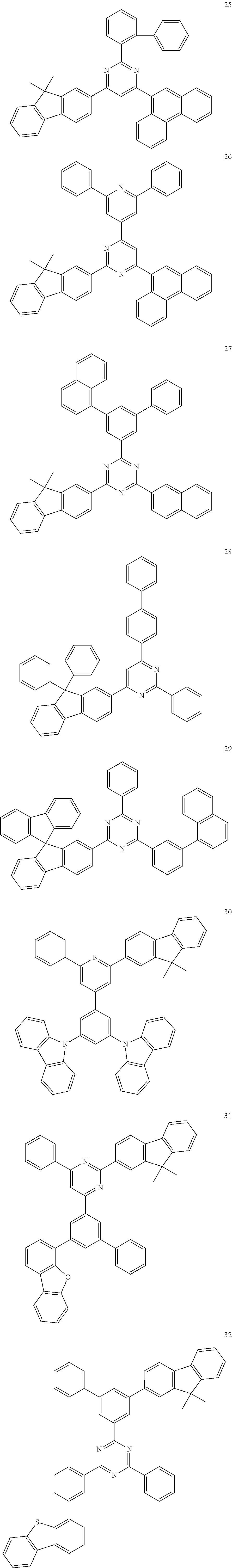

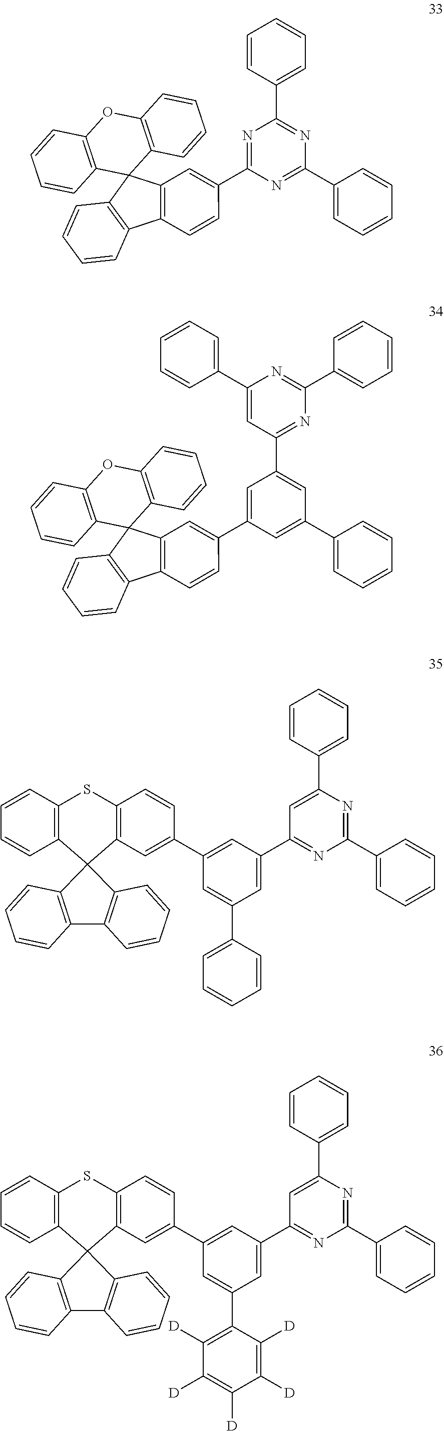 [SMILES: c1ccc(-c2nc(-c3ccccc3)nc(-c3ccc4c(c3)C3(c5ccccc5Oc5ccccc53)c3ccccc3-4)n2)cc1 ; c1ccc(-c2cc(-c3ccc4c(c3)C3(c5ccccc5Oc5ccccc53)c3ccccc3-4)cc(-c3cc(-c4ccccc4)nc(-c4ccccc4)n3)c2)cc1 ; c1ccc(-c2cc(-c3ccc4c(c3)C3(c5ccccc5S4)c4ccccc4-c4ccccc43)cc(-c3cc(-c4ccccc4)nc(-c4ccccc4)n3)c2)cc1 ; [2H]c1c([2H])c([2H])c(-c2cc(-c3ccc4c(c3)C3(c5ccccc5S4)c4ccccc4-c4ccccc43)cc(-c3cc(-c4ccccc4)nc(-c4ccccc4)n3)c2)c([2H])c1[2H]]

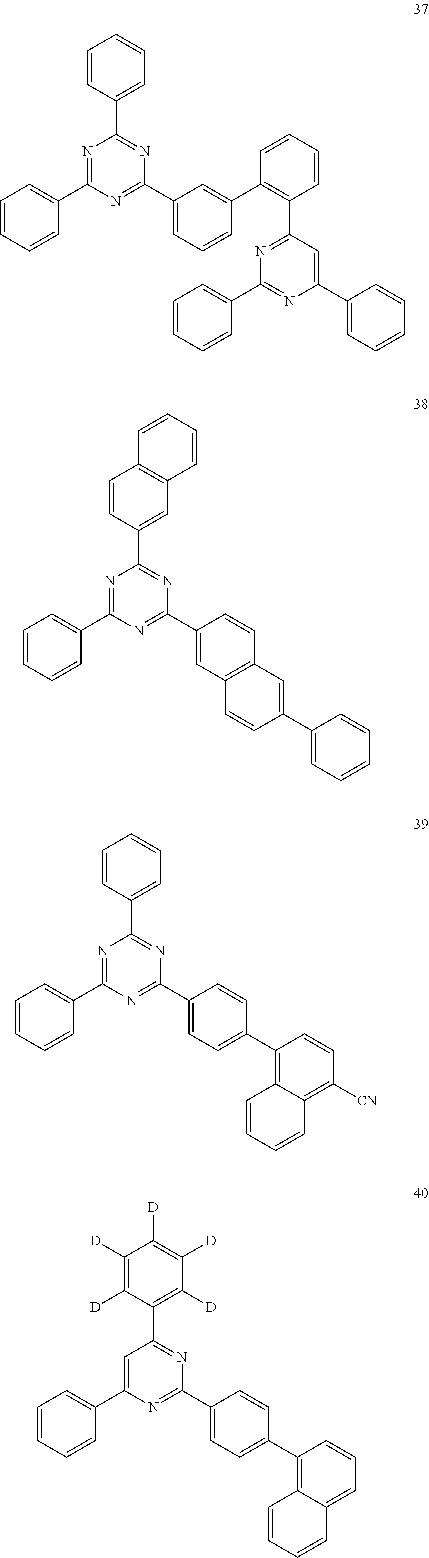 [SMILES: c1ccc(-c2cc(-c3ccccc3-c3cccc(-c4nc(-c5ccccc5)nc(-c5ccccc5)n4)c3)nc(-c3ccccc3)n2)cc1 ; c1ccc(-c2ccc3cc(-c4nc(-c5ccccc5)nc(-c5ccc6ccccc6c5)n4)ccc3c2)cc1 ; N#Cc1ccc(-c2ccc(-c3nc(-c4ccccc4)nc(-c4ccccc4)n3)cc2)c2ccccc12 ; [2H]c1c([2H])c([2H])c(-c2cc(-c3ccccc3)nc(-c3ccc(-c4cccc5ccccc45)cc3)n2)c([2H])c1[2H]]

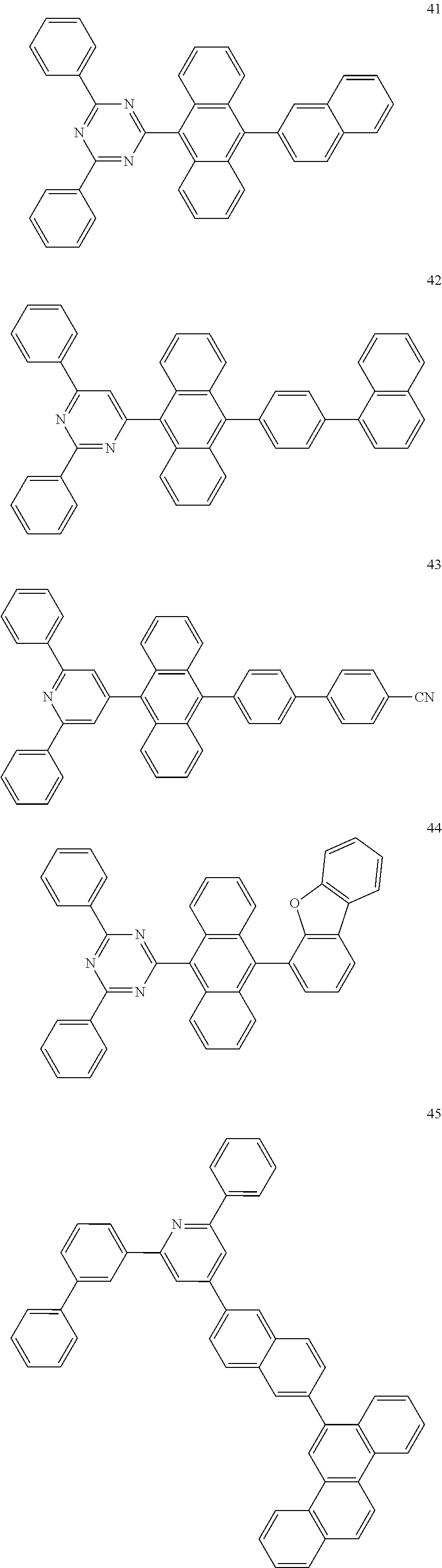

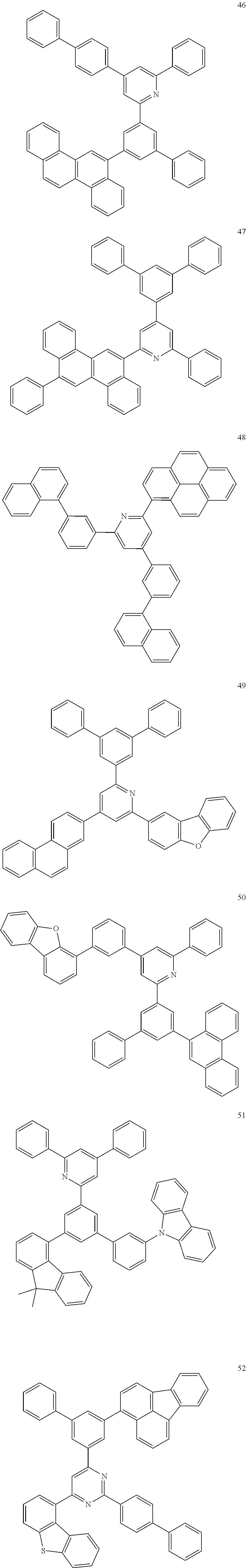

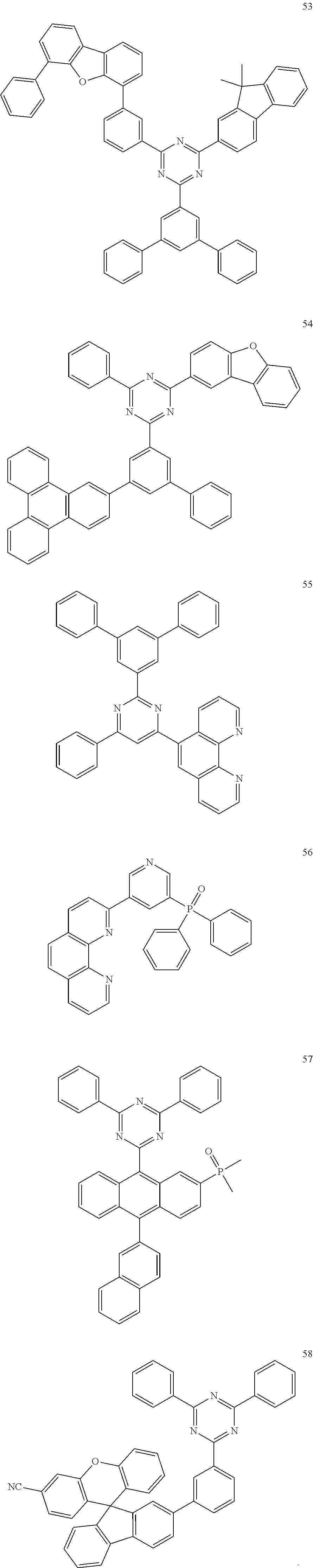

In an embodiment, three or more layers selected from the sub functional layers included in the upper functional layers UFL-B, UFL-Ba, UFL-T, and UFL-Ta included in the emission structures EU-B, EU-Ba, EU-T, and EU-Ta and the n-type charge generation layer nCGL may each independently include an electron transport material selected from Compound Group 1. In an embodiment, at least one layer among the selected three or more sub functional layers included in the upper functional layers UFL-B, UFL-Ba, UFL-T, and UFL-Ta included in the emission structures EU-B, EU-Ba, EU-T, and EU-Ta and the n-type charge generation layer nCGL may each independently include at least one electron transport material selected from Compounds 13 to 58 in Compound Group 1.

In an embodiment, all the sub functional layers included in the upper functional layers UFL-B, UFL-Ba, UFL-T, and UFL-Ta included in the emission structures EU-B, EU-Ba, EU-T, and EU-Ta and the n-type charge generation layer nCGL may each independently include an electron transport material including a monocyclic 6-membered heteroaryl group that includes N as a ring-forming atom.

The light-emitting elements ED and ED-a may each satisfy a thickness relationship of electron transport functional layers according to Expression 1 as described above; and three or more of the electron transport sub functional layers may each independently include an electron transport material including a monocyclic 6-membered heteroaryl group that includes N as a ring-forming atom, and thus the light-emitting elements ED and ED-a may exhibit characteristics of excellent light emission efficiency and a long lifespan.

The light-emitting elements ED and ED-a may include an electron transport material of the related art, in addition to an electron transport material of Compound Group 1, in at least one of the upper functional layers UFL-B, UFL-Ba, UFL-T, and UFL-Ta and the n-type charge generation layer nCGL. In an embodiment, among the sub functional layers included in the first upper functional layers UFL-B and UFL-Ba and the second upper functional layers UFL-T and UFL-Ta, the remaining sub functional layers that do not include an electron transport material of Compound Group 1 may include an electron transport material of the related art. In an embodiment, the sub functional layers included in the first upper functional layers UFL-B and UFL-Ba and the second upper functional layers UFL-T and UFL-Ta that include an electron transport material of Compound Group 1 may further include an electron transport material of the related art.

For example, the first upper functional layers UFL-B and UFL-Ba and the second upper functional layers UFL-T and UFL-Ta may each independently further include an anthracene-based compound, in addition to an electron transport material of Compound Group 1. However, embodiments are not limited thereto, and the upper functional layers UFL-B and UFL-T may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the first upper functional layers UFL-B and UFL-Ba and the second upper functional layers UFL-T and UFL-Ta may each independently include: a metal halide such as LiF, NaCl, CsF, RbCl, RbI, CuI, and KI; a lanthanide such as Yb; or a co-deposited material of a metal halide and a lanthanide. For example, the first upper functional layers UFL-B and UFL-Ba and the second upper functional layers UFL-T and UFL-Ta may include KI:Yb, RbI:Yb, LiF:Yb, etc. as a co-deposited material. The first upper functional layers UFL-B and UFL-Ba and the second upper functional layers UFL-T and UFL-Ta may include a metal oxide such as Li₂O and BaO, 8-hydroxyl-lithium quinolate (Liq), or the like, but embodiments are not limited thereto. In an embodiment, the first upper functional layers UFL-B and UFL-Ba and the second upper functional layers UFL-T and UFL-Ta may include a mixture of an electron transport material and insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The first upper functional layers UFL-B and UFL-Ba and the second upper functional layers UFL-T and UFL-Ta may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the materials described above, but embodiments are not limited thereto.

The lower functional layers LFL-B, LFL-Ba, LFL-T, and LFL-Ta included in the emission structures EU-B, EU-Ba, EU-T, and EU-Ta may each perform a hole transport function. The lower functional layers LFL-B, LFL-Ba, LFL-T, and LFL-Ta may each independently have a structure consisting of a layer consisting of a single material, a structure consisting of a layer including different materials, or a structure including multiple layers including different materials.

In an embodiment, the first lower functional layers LFL-B and LFL-Ba and the second lower functional layers LFL-T and LFL-Ta may each independently include a hole transport material of the related art. For example, the first lower functional layers LFL-B and LFL-Ba and the second lower functional layers LFL-T and LFL-Ta may each independently further include a phthalocyanine compound such as copper phthalocyanine, N1,N1′-([1,1′-biphenyl]-4,4′-diyl)bis(N1-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino) triphenylamine (TDATA), 4,4′,4″-tris[N-(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB (or NPD, α-NPD)), triphenylamine-containing polyether ketone (TPAPEK), 4-isopropyl-4′-methyldiphenyliodonium [tetrakis(pentafluorophenyl) borate], dipyrazino[2,3-f:2′,3′-h] quinoxaline-2,3,6,7,10,11-hexacarbonitrile (HATCN), etc.

The first lower functional layers LFL-B and LFL-Ba and the second lower functional layers LFL-T and LFL-Ta may each independently include a carbazole-based derivative such as N-phenylcarbazole and polyvinylcarbazole, a fluorene-based derivative, a triphenylamine-based derivative such as 4,4′,4″-tris(N-carbazolyl)triphenylamine (TCTA) or N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the first lower functional layers LFL-B and LFL-Ba and the second lower functional layers LFL-T and LFL-Ta may each independently include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

The first lower functional layers LFL-B and LFL-Ba and the second lower functional layers LFL-T and LFL-Ta may each independently further include a charge generation material to improve conductivity, in addition to the materials described above. The charge generation material may be uniformly or non-uniformly dispersed in the first lower functional layers LFL-B and LFL-Ba and the second lower functional layers LFL-T and LFL-Ta. The charge generation material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

In the light-emitting elements ED and ED-a respectively illustrated in FIGS. 4 and 5, the emission layers EML-B and EML-T are respectively disposed on the lower functional layers LFL-B, LFL-Ba, LFL-T, and LFL-Ta. The emission layers EML-B and EML-T may each independently have a structure consisting of a layer consisting of a single material, a structure consisting of a layer including different materials, or a structure including multiple layers including different materials. The emission layers EML-B and EML-T may each independently include a fluorescent light-emitting material or a phosphorescent light-emitting material. The emission layers EML-B and EML-T may each independently include a host material. In an embodiment, at least one of the emission layers EML-B and EML-T may each independently include a hole transport host and an electron transport host.

In the light-emitting elements ED and ED-a, the emission layers EML-B and EML-T may each independently include an anthracene derivative, a pyrene derivative, a fluoranthene derivative, a chrysene derivative, a dihydrobenzanthracene derivative, a triphenylene derivative, or the like. For example, the emission layers EML-B and EML-T may each independently include an anthracene derivative, a pyrene derivative, or the like. However, embodiments are not limited thereto, and the emission layers EML-B and EML-T may include a light-emitting material of the related art.

The emission layers EML-B and EML-T may each independently include a host material and a dopant material. In the light-emitting elements ED and ED-a, the emission layers EML-B and EML-T may each independently include a host material of the related art and a dopant material of the related art. The emission layers EML-B and EML-T may each independently include, as a host material, an anthracene derivative, a pyrene derivative, a fluoranthene derivative, a chrysene derivative, a dihydrobenzanthracene derivative, a triphenylene derivative, or the like. The emission layers EML-B and EML-T may each independently further include a host material of the related art. For example, the emission layers EML-B and EML-T may each independently include, as a host material, at least one of bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), poly(N-vinylcarbazole) (PVK), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the emission layers EML-B and EML-T may each independently further include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl) vinyl)phenyl)-N-phenylbenzenamine (N-BDAVBi)), 4,4′-bis[2-(4-(N,N-diphenylamino)phenyl)vinyl]biphenyl (DPAVBi), perylene or a derivative thereof (e.g., 2, 5, 8, 11-tetra-t-butylperylene (TBP)), pyrene or a derivative thereof (e.g., 1, 1-dipyrene, 1,4-dipyrenylbenzene, 1,4-bis(N, N-diphenylamino) pyrene), etc.

The emission layers EML-B and EML-T may each independently further include a phosphorescent dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium (III) bis(4,6-difluorophenylpyridinato-N,C2′) picolinate (FIrpic), bis(2,4-difluorophenylpyridinato)-tetrakis(1-pyrazolyl) borate iridium (III) (Fir6), or platinum octaethyl porphyrin (PtOEP) may be used as a phosphorescent dopant. However, embodiments are not limited thereto.

In an embodiment, the emission layers EML-B and EML-T may each independently include a quantum dot material.

In the light-emitting elements ED and ED-a, the first emission layer EML-B of the lower emission structures EU-B and EU-Ba and the second emission layer EML-T of the upper emission structures EU-T and EU-Ta may overlap each other in a thickness direction and may emit light in a same wavelength region. The first emission layer EML-B and the second emission layer EML-T may include a same light-emitting material. However, embodiments are not limited thereto. In FIGS. 4 and 5, the first emission layer EML-B and the second emission layer EML-T are each illustrated as a single layer, but embodiments are not limited thereto, and the first emission layer EML-B and the second emission layer EML-T may each independently include multiple sub emission layers.

In the light-emitting elements ED and ED-a, the charge generation layer CGL may include an n-type aryl amine-based material or a p-type metal oxide. For example, the charge generation layer CGL may include a charge generation compound composed of an aryl amine-based organic compound, a metal, a carbide, a fluoride, a metal oxide, or a mixture thereof.

For example, the n-type charge generation layer nCGL may include bathophenanthroline (Bphen), α-NPD, 2-TNATA, TDATA, MTDATA, spiro-TAD, or spiro-NPB. For example, the p-type charge generation layer pCGL may include a metal such as cesium (Cs), molybdenum (Mo), vanadium (V), titanium (Ti), tungsten (W), barium (Ba), or lithium (Li). Examples of a metal oxide, a carbide, or a fluoride may include Re₂O₇, MoO₃, V₂O₅, WO₃, TiO₂, Cs₂CO₃, BaF, LiF, or CsF.

The light-emitting element ED-1 illustrated in FIG. 6 may differ from the light-emitting elements ED and ED-a respectively shown in FIGS. 4 and 5 at least with respect to the number of stacked emission structures. The components of the light-emitting element ED-1 illustrated in FIG. 6 may be the same as described with respect to the components of the light-emitting elements ED and ED-a according to FIGS. 4 and 5 as explained above.

Referring to FIG. 6, the light-emitting element ED-1 may include (n−1) charge generation layers CGL1, CGL2, . . . , and CGL (n−1) and n emission structures EU1, EU2, . . . , and EUn disposed between the first electrode AE and the second electrode CE. Among the n emission structures EU1, EU2, . . . , and EUn, the first emission structure EU1 may correspond to the lower emission structures EU-B and EU-Ba as respectively described with reference to FIGS. 4 and 5, and the n-th emission structure EUn may correspond to the upper emission structures EU-T and EU-Ta as respectively described with reference to FIGS. 4 and 5.

According to embodiments, the light-emitting element ED-1 illustrated in FIG. 6 may satisfy Expression 1:

$$50 nm \geq {d}_{TOP} > {d}_{LOW} > 15 nm \qquad [ Expression 1 ]$$

In Expression 1, d_{LOW} may be a sum di of a thickness of an upper functional layer UFL-1 included in the first emission structure EU1, which is a lower emission structure adjacent to the first electrode AE among the n emission structures, and a thickness of an n-type charge generation layer nCGL1 directly disposed on the first emission structure EU1; and d_{TOP} may be a thickness dₙ of an upper functional layer UFL-n included in the n-th emission structure EUn, which is an upper emission structure adjacent to the second electrode CE among the n emission structures.

Thus, the light-emitting element ED-1 illustrated in FIG. 6 may also satisfy the thickness relationship of Expression 1, wherein the light-emitting element ED-1 includes the n emission structures, such that a thickness of an n-th upper functional layer UFL-n including an n-th electron transport layer ETL-n and an n-th electron transport auxiliary layer BFL-n, in which the n-th upper functional layer UFL-n performs an electron transport function in the upper emission structure EUn and which is disposed adjacent to the second electrode CE, may be greater than a sum of a thickness of an n-type charge generation layer nCGL1 and a thickness of a first upper functional layer UFL-1 including a first electron transport layer ETL-1 and a first electron transport auxiliary layer BFL-1, in which the first upper functional layer UFL-1 performs an electron transport function in the lower emission structure EU1 and which is disposed adjacent to the first electrode AE.

Among the (n−1) charge generation layers CGL1, CGL2, . . . , and CGL (n−1) and the n emission structures EU1, EU2, . . . , and EUn disposed between the first electrode AE and the second electrode CE, the thickness dₙ of the electron transport functional layer of the n-th emission structure EUn adjacent to the second electrode CE may be greater than each of sums of a thickness of other electron transport functional layers disposed below the n-th emission structure EUn and a thickness of n-type charge generation layers respectively adjacent thereto. For example, a sum d₂ of a thickness of an upper functional layer UFL-2 of a second emission structure EU2 and a thickness of an n-type charge generation layer nCGL2 of a second charge generation layer CGL2 may be greater than about 15 nm and smaller than the thickness dₙ of the upper functional layer UFL-n included in the n-th emission structure EUn.

Accordingly, when the thickness relation of Expression 1 is satisfied, the light-emitting element ED-1 may exhibit characteristics of excellent light emission efficiency and a long lifespan, and a display device including the light-emitting element ED-1 may exhibit characteristics of excellent display quality and a long lifespan.

Among the upper functional layers UFL-1, UFL-2, . . . , and UFL-n included in the n emission structures EU1, EU2, . . . , and EUn and the n-type charge generation layers nCGL1, nCGL2, . . . , and nCGL (n−1) in the (n−1) charge generation layers CGL1, CGL2, . . . , and CGL (n−1), three or more layers selected therefrom may each independently include an electron transport material including a monocyclic 6-membered heteroaryl group that includes N as a ring-forming atom. In an embodiment, at least one layer among the selected three or more layers may include an electron transport material including a monocyclic 6-membered heteroaryl group that includes N as a ring-forming atom, and a condensed ring that includes eight or more ring-forming carbon atoms.

The light-emitting element ED-1 may satisfy the thickness relationship of Expression 1 as described above and may include the electron transport material as described above, and thus may exhibit characteristics of high light emission efficiency and a long lifespan.

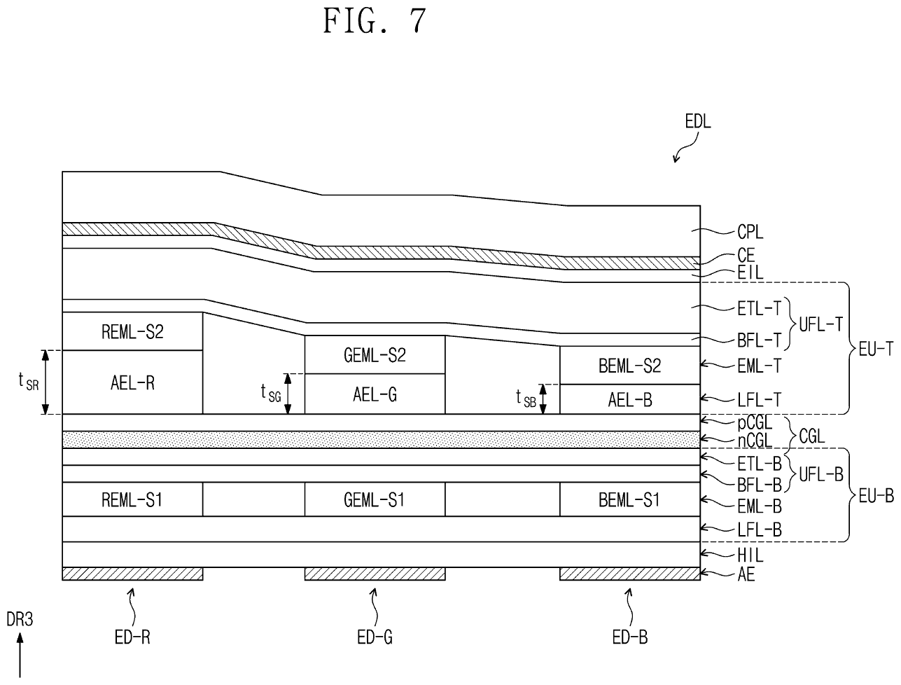

FIG. 7 is a schematic cross-sectional view of a display layer EDL according to an embodiment. FIG. 7 illustrates as an example that light-emitting elements ED-R, ED-G, and ED-B of the display layer EDL each have a structure of the light-emitting element illustrated in FIG. 4. However, embodiments are not limited thereto, and any light-emitting element having a tandem structure that satisfies the thickness relationship of Expression 1 with respect to the electron transport functional layers as described above may also be used in the display layer EDL.

The display layer EDL according to an embodiment may include a first electrode AE, a hole injection layer HIL, a lower emission structure EU-B, a charge generation layer CGL, an upper emission structure EU-T, an electron injection layer EIL, a second electrode CE, and a capping layer CPL. The lower emission structure EU-B may include a first lower functional layer LFL-B, a first emission layer EML-B, and a first upper functional layer UFL-B. The upper emission structure EU-T may include a second lower functional layer LFL-T, a second emission layer EML-T, and a second upper functional layer UFL-T. The charge generation layer CGL may include an n-type charge generation layer nCGL and a p-type charge generation layer pCGL.

The first electrode AE may be separated and disposed in each of first to third light-emitting elements ED-R, ED-G, and ED-B. In an embodiment, the hole injection layer HIL, the first lower functional layer LFL-B, the first upper functional layer UFL-B, the charge generation layer CGL, the second upper functional layer UFL-T, the electron injection layer EIL, the second electrode CE, and the capping layer CPL may each be provided as a common layer throughout the first to third light-emitting elements ED-R, ED-G, and ED-B. However, embodiments are not limited thereto.

In an embodiment, the first light-emitting element ED-R may include a first sub red light emission layer REML-S1 as the first emission layer EML-B, a second sub red light emission layer REML-S2 as the second emission layer EML-T, and a red light emission auxiliary layer AEL-R as the second lower functional layer LFL-T.

In an embodiment, the second light-emitting element ED-G may include a first sub green light emission layer GEML-S1 as the first emission layer EML-B, a second sub green light emission layer GEML-S2 as the second emission layer EML-T, and a green light emission auxiliary layer AEL-G as the second lower functional layer LFL-T. In an embodiment, the third light-emitting element ED-B may include a first sub blue light emission layer BEML-S1 as the first emission layer EML-B, a second sub blue light emission layer BEML-S2 as the second emission layer EML-T, and a blue light emission auxiliary layer AEL-B as the second lower functional layer LFL-T.

The red light emission auxiliary layer AEL-R, the green light emission auxiliary layer AEL-G, and the blue light emission auxiliary layer AEL-B may be separated and respectively disposed in the first to third light-emitting elements ED-R, ED-G, and ED-B. In case that an emission auxiliary layer is included as the second lower functional layer LFL-T, a thickness of the second lower functional layer LFL-T may be different according to a wavelength of light respectively emitted from the first to third light-emitting elements ED-R, ED-G, and ED-B. In an embodiment, a thickness t_{SR} of the red light emission auxiliary layer AEL-R of the first light-emitting element ED-R that emits red light may be greater than a thickness t_{SG} of the green light emission auxiliary layer AEL-G of the second light-emitting element ED-G that emits green light. In an embodiment, the thickness t_{SG} of the green light emission auxiliary layer AEL-G of the second light-emitting element ED-G that emits green light may be greater than a thickness t_{SB} of the blue light emission auxiliary layer AEL-B of the third light-emitting element ED-B that emits blue light.

In the display layer EDL illustrated in FIG. 7, a thickness of the second upper functional layer UFL-T may be greater than a sum of a thickness of the first upper functional layer UFL-B and the n-type charge generation layer nCGL, wherein the thickness of the second upper functional layer UFL-T may be equal to or less than about 50 nm, in accordance with Expression 1 as explained above. In the display layer EDL illustrated in FIG. 7, a sum of a thickness of the first upper functional layer UFL-B and the n-type charge generation layer nCGL may be greater than about 15 nm, in accordance with Expression 1 as explained above. By satisfying the thickness relationship of Expression 1, the first to third light-emitting elements ED-R, ED-G, and ED-B may exhibit characteristics of high efficiency and a long lifespan, such that a display device including the light-emitting elements ED-R, ED-G, and ED-B may exhibit characteristics of improved display quality due to excellent efficiency and improved reliability due to a long lifespan.

Hereinafter, evaluation results of characteristics of a light-emitting element according to an embodiment will be described with reference to the Examples and Comparative Examples. The Examples described below are only provided to in understanding the disclosure, and the scope thereof is not limited thereto.

### <Manufacturing of Light-Emitting Element>

Each light-emitting element according to Examples 1 to 4 and Comparative Examples 1 to 5 was manufactured as a tandem light-emitting element by forming a first electrode on a glass substrate, forming a lower emission structure, forming a charge generation layer, forming an upper emission structure, forming a second electrode, and forming a capping layer. Each tandem light-emitting element according to the Examples and the Comparative Examples was manufactured on the basis of the structure of the light-emitting element illustrated in FIG. 4. The light-emitting elements of Examples 1 to 4 and Comparative Examples 1 to 5 were evaluated by evaluating blue light-emitting structures included therein.

Each light-emitting element according to the Examples and Comparative Examples was manufactured through the following method. A hole injection layer was formed by depositing Compound HT1 doped with F4-TCNQ (about 2%) at about 10 nm on a first electrode of ITO/Ag/ITO (about 120 Å/about 500 Å/about 120 Å). A first lower functional layer was formed by depositing only HT1 at about 20 nm. A first emission layer of about 20 nm thickness was formed by co-depositing Compound BH and Compound BD on the first lower functional layer. Compounds BH and BD were co-deposited at a weight ratio of about 97:3. A first electron transport auxiliary layer was formed by depositing Compound BF1 at about 5 nm on the first emission layer, and a first electron transport layer was formed by depositing Compound ET1 at about 10 nm on the first electron transport auxiliary layer.

A charge generation layer was formed on the first electron transport layer, by depositing bathophenanthroline (Bphen) doped with Li (about 2%) at about 10 nm and depositing Compound HT1 doped with F4-TCNQ (about 5%) at about 5 nm.

An upper emission structure was formed on the charge generation layer. A second lower functional layer was formed by depositing Compound HT1 at about 40 nm on the charge generation layer and depositing Compound HT2 at about 10 nm thereon. A second emission layer was formed on the second lower functional layer with a same material and structure as described above for the lower emission structure. A second electron transport auxiliary layer was formed by depositing Compound BF2 at about 5 nm on the second emission layer, and a second electron transport layer was formed as a common layer by depositing Compound ET2 at about 30 nm.

A second electrode having a thickness of about 110 Å was formed by depositing Mg:Ag (about 9:1) on the upper emission structure. A capping layer was formed as a common layer by depositing Compound CP5 at about 60 nm on the second electrode, and thus a light-emitting element was manufactured. Each layer was formed through a vacuum deposition method.

Materials used for manufacturing each light-emitting element of Example and Comparative Example are shown below.

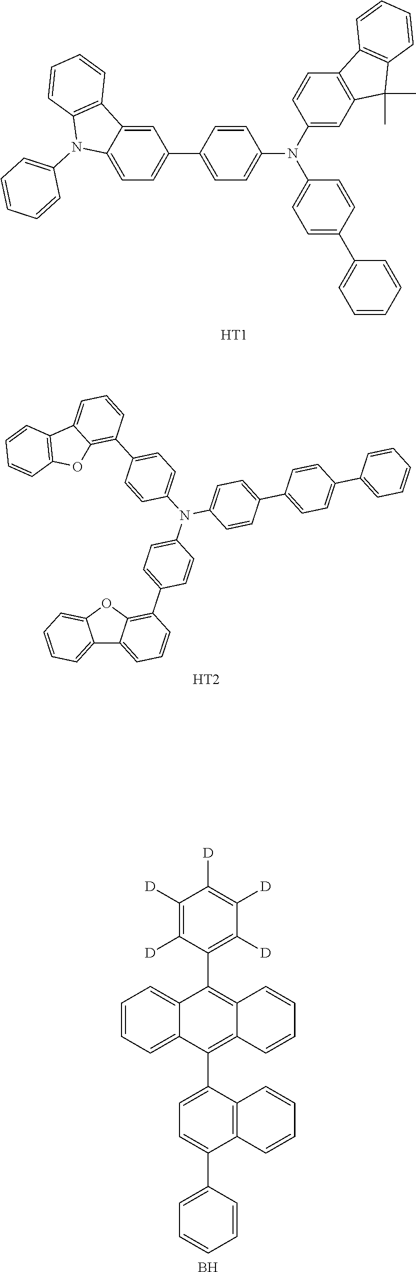

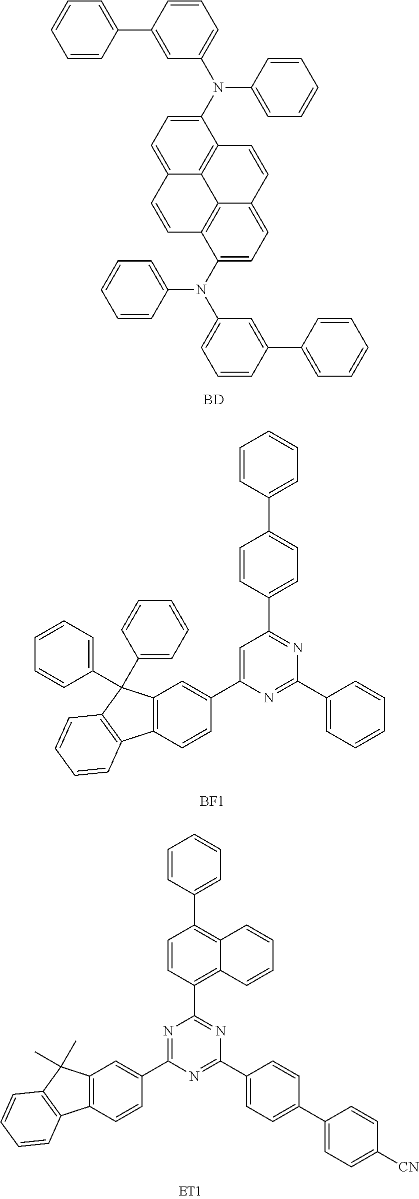

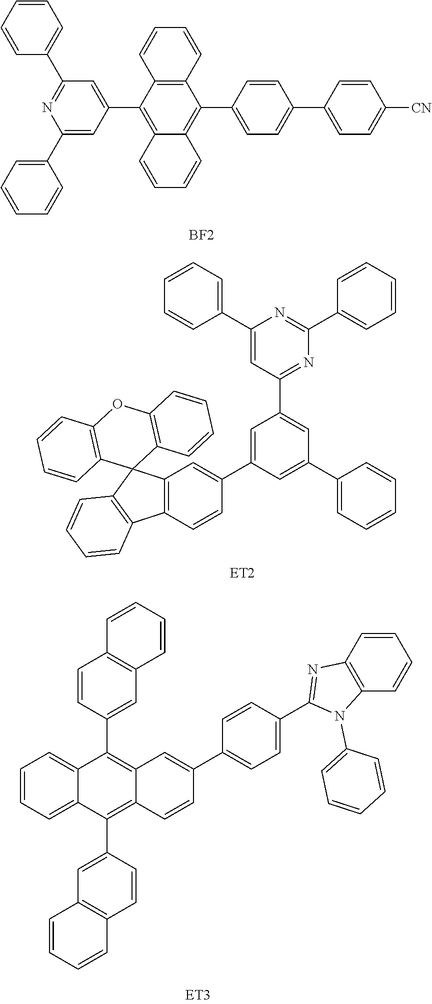

Materials for a first upper functional layer, a second upper functional layer, and an n-type charge generation layer according to Examples 1 to 4 and Comparative Examples 1 to 5 are shown in Table 1.

TABLE 1

| | First | | | Second | |
|---|---|---|---|---|---|
| | electron | First | n-type | electron | Second |
| | transport | electron | charge | transport | electron |
| | auxiliary | transport | generation | auxiliary | transport |
| | layer | layer | layer | layer | layer |
| Division | (BFL-B) | (ETL-B) | (nCGL) | (BFL-T) | (ETL-T) |
| Example 1 | BF1 | ET1 | Bphen | BF2 | ET2 |
| Example 2 | BF1 | ET1 | Bphen | BF2 | ET2 |
| Example 3 | BF1 | ET1 | Bphen | BF2 | ET2 |
| Example 4 | BF1 | ET1 | Bphen | BF2 | ET2 |
| Comparative | BF1 | ET1 | Bphen | BF2 | ET2 |
| Example 1 | | | | | |
| Comparative | BF1 | ET1 | Bphen | BF2 | ET2 |
| Example 2 | | | | | |
| Comparative | BF1 | ET1 | Bphen | BF2 | ET2 |
| Example 3 | | | | | |
| Comparative | BF1 | ET3 | Bphen | BF2 | ET3 |
| Example 4 | | | | | |
| Comparative | BF1 | ET1 | Bphen | BF2 | ET2 |
| Example 5 | | | | | |

### <Evaluation of Light-Emitting Element>

Table 2 shows a thickness of each electron transport functional layer in the Examples and Comparative Examples, and the resulting characteristics of light emission efficiency and lifespan of the Examples and Comparative Examples. The characteristics of efficiency and lifespan are shown as relative values when efficiency and lifespan of Comparative Example 1 is set to 100%.

The efficiency and lifespan shown in Table 2 were each measured by using Keithley SMU 236 and a luminance meter PR650 Spectroscan Source Measurement Unit. (PhotoResearch Inc.), and the results are shown as relative values. The lifespan in Table 2 is a T95 lifespan, which is obtained by measuring time taken for luminance to be reduced to about 95% when an initial luminance is set to 100% under a condition of a current density of about 10 mA/cm².

TABLE 2

| | Thickness of | Thickness | Thickness | Thickness of | Thickness | | |
|---|---|---|---|---|---|---|---|
| | first electron | of first | of n-type | second electron | of second | | |
| | transport | electron | charge | transport | electron | | |
| | auxiliary | transport | generation | auxiliary | transport | Efficiency | Lifespan |
| Division | layer (nm) | layer (nm) | layer (nm) | layer (nm) | layer (nm) | (%) | (%) |
| Example 1 | 5 | 10 | 10 | 5 | 30 | 110 | 170 |
| Example 2 | 5 | 15 | 10 | 5 | 30 | 110 | 160 |
| Example 3 | 10 | 10 | 10 | 10 | 25 | 102 | 210 |
| Example 4 | 10 | 10 | 15 | 10 | 35 | 110 | 190 |
| Comparative | 10 | 15 | 10 | 5 | 30 | 100 | 100 |
| Example 1 | | | | | | | |
| Comparative | 5 | 10 | 10 | 10 | 45 | 85 | 80 |
| Example 2 | | | | | | | |
| Comparative | 5 | 5 | 5 | 5 | 30 | 100 | 65 |
| Example 3 | | | | | | | |
| Comparative | 5 | 10 | 10 | 5 | 30 | 95 | 100 |
| Example 4 | | | | | | | |
| Comparative | 10 | 15 | 15 | 5 | 30 | 90 | 95 |
| Example 5 | | | | | | | |

Referring to the results of Table 2, the Examples each satisfy a thickness relationship in which a sum of thicknesses of a second electron transport auxiliary layer and a second electron transport layer is greater than a sum of thicknesses of a first electron transport auxiliary layer, a first electron transport layer, and an n-type charge generation layer, such that the sum of thicknesses of the first electron transport auxiliary layer, the first electron transport layer, and the n-type charge generation layer is greater than about 15 nm, and the sum of the thicknesses of the second electron transport auxiliary layer and the second electron transport layer is equal to or less than about 50 nm, such that each of the Examiner exhibited characteristics of excellent efficiency and a long lifespan as compared to Comparative Example 1 to Comparative Example 3 that do not satisfy such a thickness relationship. Example 1 to Example 4 also exhibited characteristics of excellent efficiency and a long lifespan as compared to Comparative Example 5, in which a sum of thicknesses of electron transport functional layers included in an upper emission structure is smaller than a sum of thicknesses of electron transport functional layers included in a lower emission structure.

The Examples are further characterized wherein among a first electron transport auxiliary layer, a first electron transport layer, an n-type charge generation layer, a second electron transport auxiliary layer, and a second electron transport layer, three or more layers selected therefrom include an electron transport material such as BF1, ET1, BF2, and ET2 as described above, and the Examples exhibited characteristics of excellent light emission efficiency and a long lifespan as compared to Comparative Example 4, in which only two layers include such an electron transport material.

In a light-emitting element according to an embodiment, a light-emitting element having a stacked structure may be optimized so as to satisfy a thickness relationship in which a sum of thicknesses of electron transport functional layers included in an upper emission structure is greater than a sum of thicknesses of electron transport functional layers included in a lower emission structure, the sum of the thicknesses of the electron transport functional layers included in the lower emission structure is greater than about 15 nm, and the sum of the thicknesses of the electron transport functional layers included in the upper emission structure is equal to or less than about 50 nm, and thus characteristics of excellent light emission efficiency and a long lifespan may be exhibited. In a light-emitting element according to an embodiment, three or more electron transport functional layers among electron transport functional layers included in an upper emission structure and electron transport functional layers included in a lower emission structure may include an electron transport material including a monocyclic 6-membered heteroaryl group that includes N as a ring-forming atom, and thus characteristics of high efficiency and a long lifespan may be exhibited. A display device according to an embodiment including at least one light-emitting element having a stacked structure as described above may exhibit excellent light emission efficiency, display quality, and characteristics of long lifespan.

A light-emitting element according to an embodiment may include multiple emission structures, and a relationship of a thickness of an electron transport region in an emission structure disposed in an upper portion and a thickness of an electron transport region in an emission structure disposed in a lower portion among the multiple emission structures may be optimized, and thus characteristics of improved light emission efficiency and excellent lifespan may be exhibited.

In a display device according to an embodiment, a thickness relationship of electron transport regions in multiple emission structures may be optimized, and thus characteristics of excellent display quality and improved lifespan may be exhibited.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode facing the first electrode;
a lower emission structure disposed between the first electrode and the second electrode, the lower emission structure including a first lower functional layer, a first emission layer, and a first upper functional layer that are sequentially stacked;
an upper emission structure disposed on the lower emission structure, the upper emission structure including a second lower functional layer, a second emission layer, and a second upper functional layer that are sequentially stacked; and
a charge generation layer disposed between the lower emission structure and the upper emission structure, the charge generation layer including an n-type charge generation layer and a p-type charge generation layer, wherein
the light-emitting element satisfies Expression 1:
$$50 nm \geq {d}_{TOP} > {d}_{LOW} > 15 nm \qquad [ Expression 1 ]$$
wherein in Expression 1,
d_{LOW} is a sum of a thickness of the first upper functional layer and a thickness of the n-type charge generation layer, and
d_{TOP} is a thickness of the second upper functional layer.

2. The light-emitting element of claim 1, wherein
the first upper functional layer, the second upper functional layer, and the n-type charge generation layer each comprise an electron transport material, and
the first lower functional layer and the second lower functional layer each comprise a hole transport material.

3. The light-emitting element of claim 1, wherein
the first upper functional layer comprises:
a first electron transport layer directly disposed under the n-type charge generation layer; and
a first electron transport auxiliary layer directly disposed under the first electron transport layer, and
the second upper functional layer comprises:
a second electron transport auxiliary layer directly disposed on the second emission layer; and
a second electron transport layer directly disposed on the second electron transport auxiliary layer.

4. The light-emitting element of claim 3, wherein three or more layers selected from the first electron transport layer, the first electron transport auxiliary layer, the n-type charge generation layer, the second electron transport auxiliary layer, and the second electron transport layer each independently comprise an electron transport material including a monocyclic 6-membered heteroaryl group that includes N as a ring-forming atom.

5. The light-emitting element of claim 4, wherein the electron transport material that is comprised in at least one layer among the selected three or more layers includes a monocyclic 6-membered heteroaryl group that includes N as a ring-forming atom and a condensed ring that includes eight or more ring-forming carbon atoms.

6. The light-emitting element of claim 5, wherein the condensed ring is naphthalene, anthracene, fluorene, phenanthrene, spiro-bifluorene, fluoranthene, chrysene, quinoline, quinazoline, phenanthroline, dibenzofuran, or dibenzothiophene.

7. The light-emitting element of claim 4, wherein the electron transport material is a compound selected from Compound Group 1:

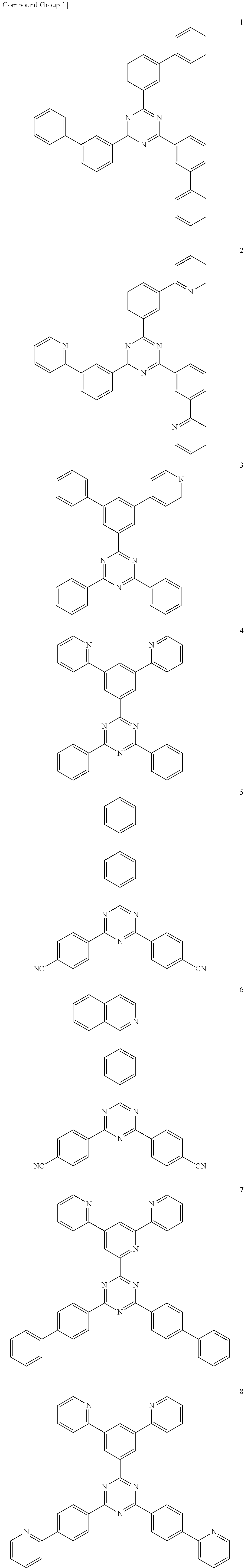

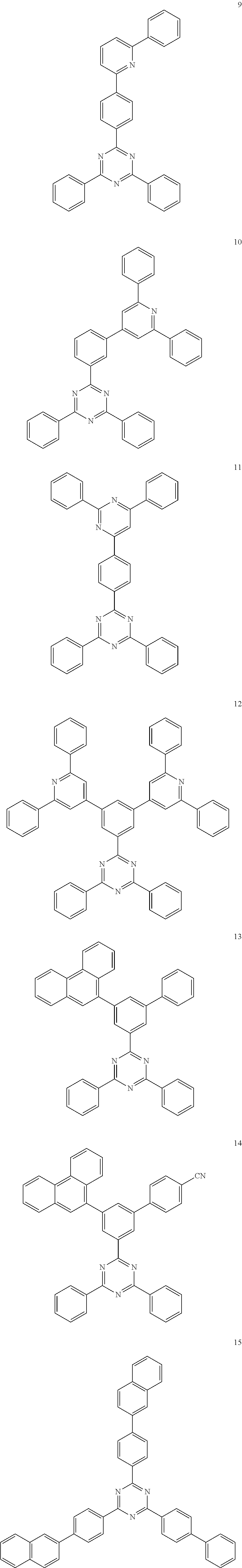

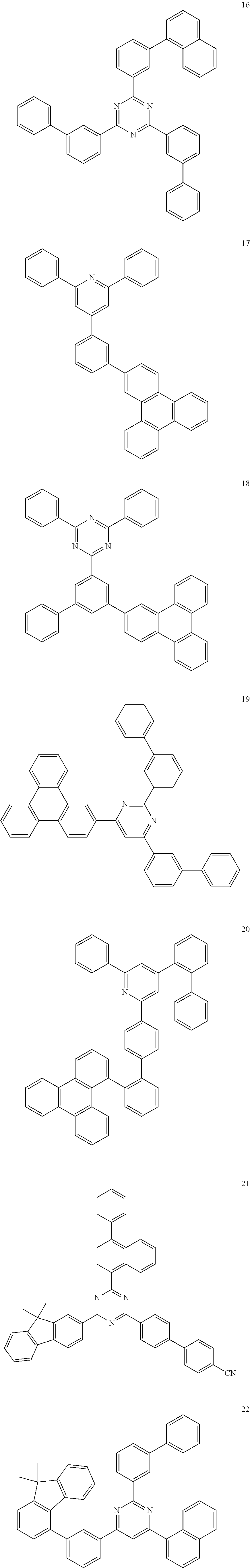

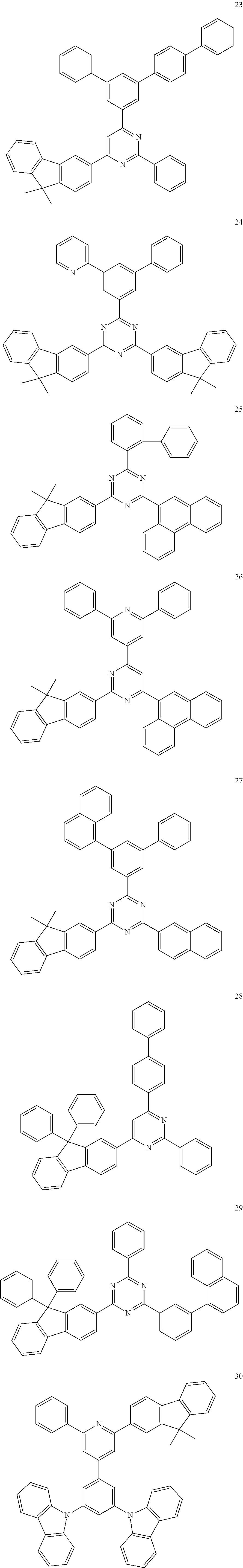

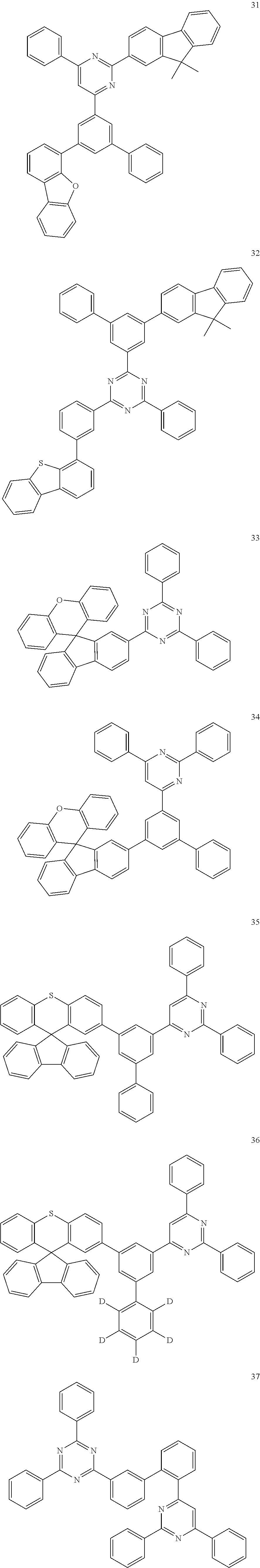

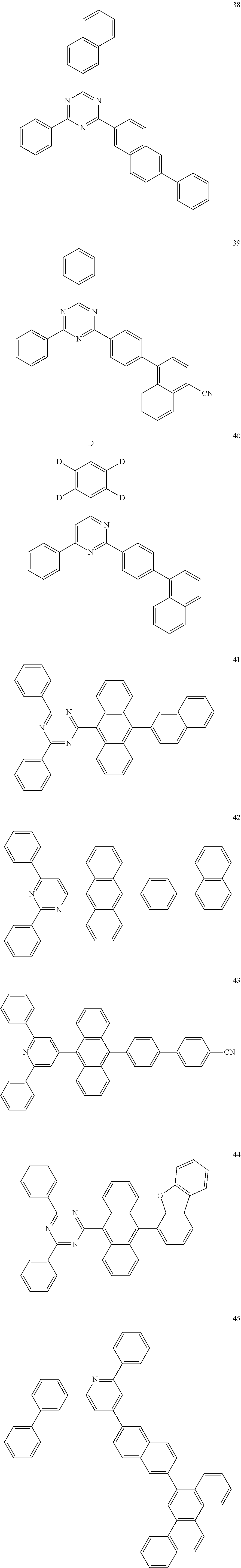

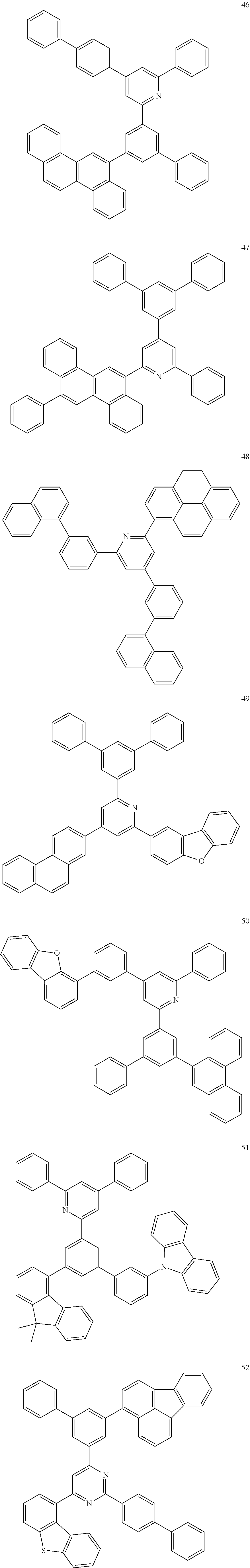

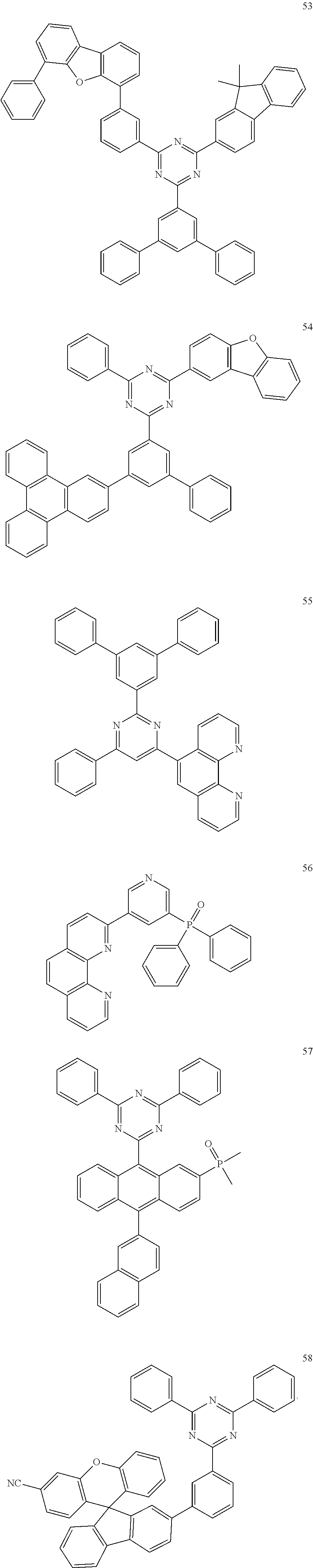

8. The light-emitting element of claim 1, wherein the first emission layer and the second emission layer emit light in a same wavelength region.

9. The light-emitting element of claim 1, wherein
at least one of the first upper functional layer and the second upper functional layer each independently comprises three or more electron transport functional layers, and
the electron transport functional layers are each an electron injection layer, an electron transport layer, or a hole blocking layer.

10. The light-emitting element of claim 1, wherein
at least one of the first lower functional layer and the second lower functional layer each independently comprises three or more hole transport functional layers, and
the hole transport functional layers are each a hole injection layer, a hole transport layer, an electron blocking layer, or an emission auxiliary layer.

11. The light-emitting element of claim 10, further comprising:
a capping layer disposed on the second electrode.

12. A light-emitting element comprising:
a first electrode;
a second electrode facing the first electrode;
a plurality of emission structures disposed between the first electrode and the second electrode, each emission structure including a lower functional layer, an emission layer, and an upper functional layer that are sequentially stacked; and
one or more charge generation layers, each charge generation layer disposed between adjacent emission structures among the plurality of emission structures, and each charge generation layer including an n-type charge generation layer and a p-type charge generation layer, wherein
the light-emitting element satisfies Expression 1:
$$50 nm \geq {d}_{TOP} > {d}_{LOW} > 15 nm \qquad [ Expression 1 ]$$
wherein in Expression 1,
d_{LOW} is a sum of a thickness of the upper functional layer of a lower emission structure that is adjacent to the first electrode and a thickness of the n-type charge generation layer directly disposed on the lower emission structure, and
d_{TOP} is a thickness of the upper functional layer of an upper emission structure that is adjacent to the second electrode.

13. The light-emitting element of claim 12, wherein
the upper functional layer of each emission structure comprises an electron transport material, and
the lower functional layer of each emission structure comprises a hole transport material.

14. The light-emitting element of claim 12, wherein
the upper functional layer of the upper emission structure comprises a plurality of upper electron transport functional layers,
the upper functional layer of the lower emission structure comprises a plurality of lower electron transport functional layers, and
three or more layers selected from the plurality of upper electron transport functional layers, the plurality of lower electron transport functional layers, and the n-type charge generation layer directly disposed on the lower emission structure each independently comprise an electron transport material including a monocyclic 6-membered heteroaryl group that includes N as a ring-forming atom.

15. The light-emitting element of claim 14, wherein the electron transport material that is comprised in at least one layer among the selected three or more layers includes a monocyclic 6-membered heteroaryl group that includes N as a ring-forming atom and a condensed ring that includes eight or more ring-forming carbon atoms.

16. The light-emitting element of claim 14, wherein the electron transport material is a compound selected from Compound Group 1:

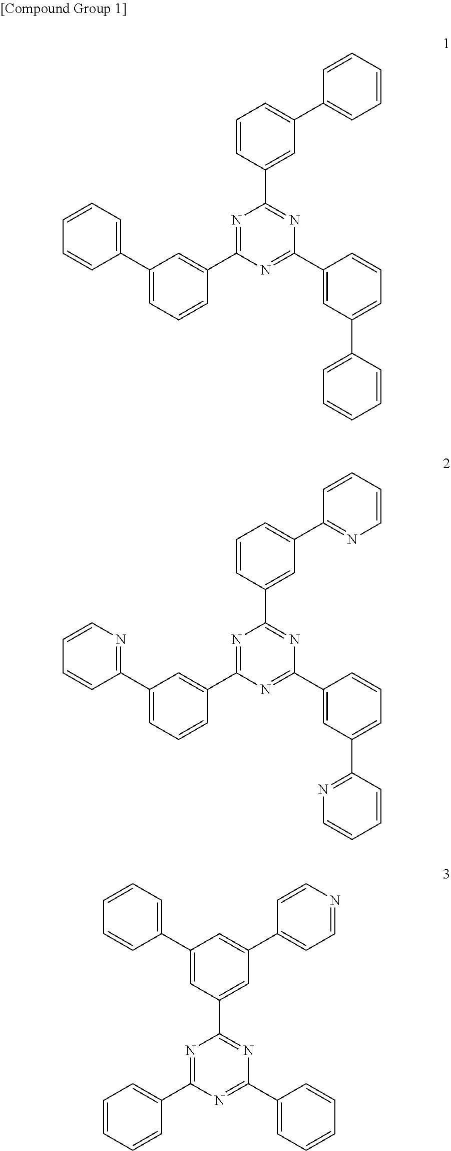 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4cccc(-c5ccccn5)c4)nc(-c4cccc(-c5ccccn5)c4)n3)c2)nc1 ; c1ccc(-c2cc(-c3ccncc3)cc(-c3nc(-c4ccccc4)nc(-c4ccccc4)n3)c2)cc1]

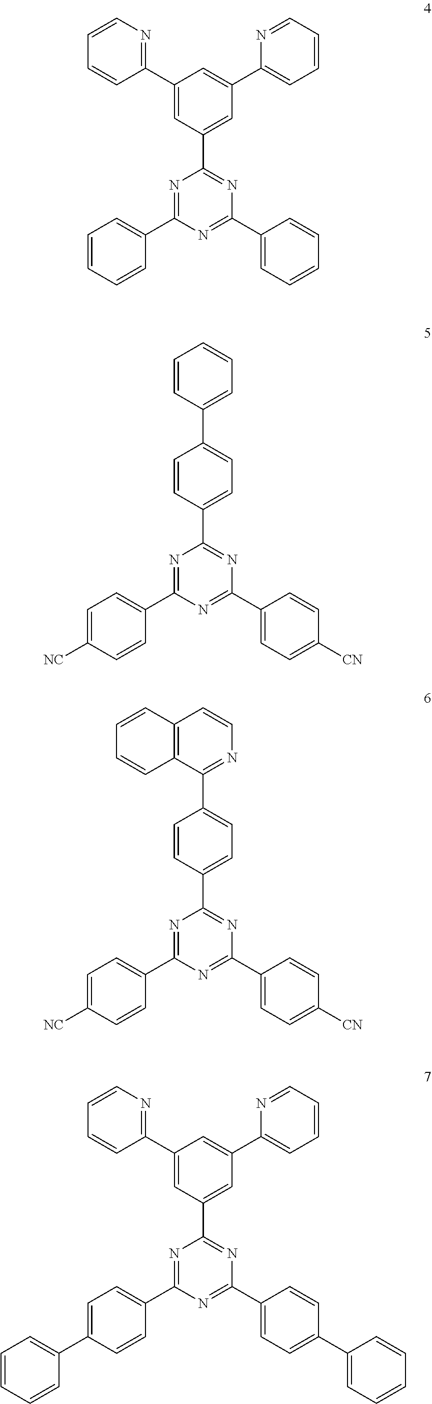 [SMILES: c1ccc(-c2nc(-c3ccccc3)nc(-c3cc(-c4ccccn4)cc(-c4ccccn4)c3)n2)cc1 ; N#Cc1ccc(-c2nc(-c3ccc(C#N)cc3)nc(-c3ccc(-c4ccccc4)cc3)n2)cc1 ; N#Cc1ccc(-c2nc(-c3ccc(C#N)cc3)nc(-c3ccc(-c4nccc5ccccc45)cc3)n2)cc1 ; c1ccc(-c2ccc(-c3nc(-c4ccc(-c5ccccc5)cc4)nc(-c4cc(-c5ccccn5)cc(-c5ccccn5)c4)n3)cc2)cc1]

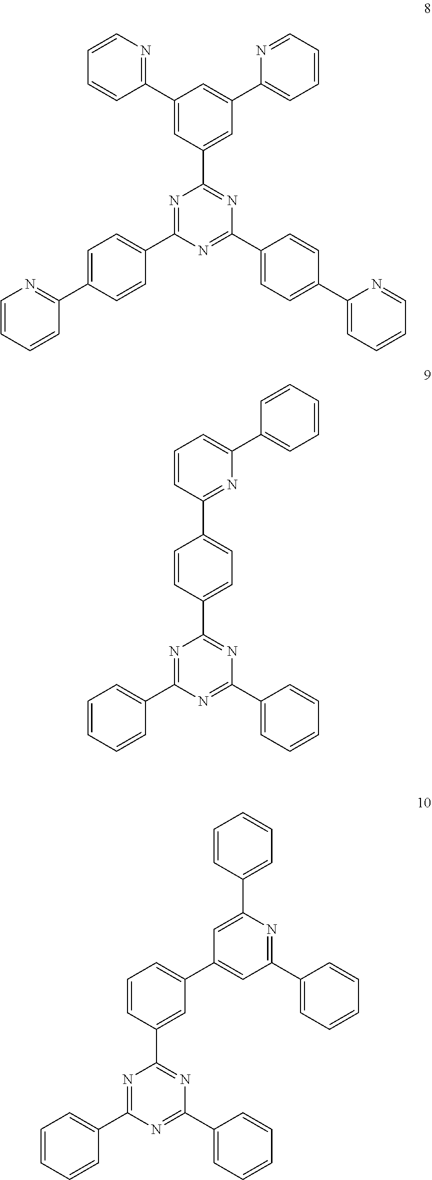 [SMILES: c1ccc(-c2ccc(-c3nc(-c4ccc(-c5ccccn5)cc4)nc(-c4cc(-c5ccccn5)cc(-c5ccccn5)c4)n3)cc2)nc1 ; c1ccc(-c2cccc(-c3ccc(-c4nc(-c5ccccc5)nc(-c5ccccc5)n4)cc3)n2)cc1 ; c1ccc(-c2cc(-c3cccc(-c4nc(-c5ccccc5)nc(-c5ccccc5)n4)c3)cc(-c3ccccc3)n2)cc1]

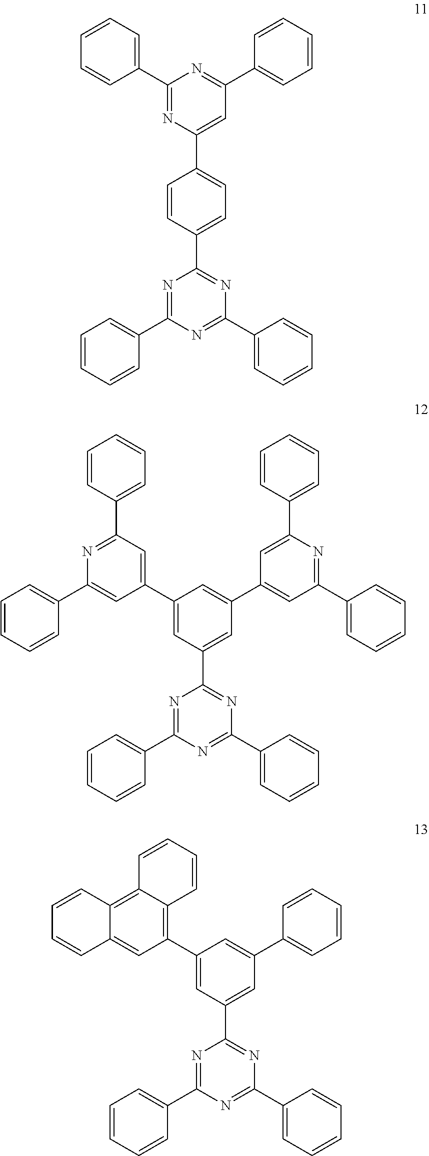 [SMILES: c1ccc(-c2cc(-c3ccc(-c4nc(-c5ccccc5)nc(-c5ccccc5)n4)cc3)nc(-c3ccccc3)n2)cc1 ; c1ccc(-c2cc(-c3cc(-c4cc(-c5ccccc5)nc(-c5ccccc5)c4)cc(-c4nc(-c5ccccc5)nc(-c5ccccc5)n4)c3)cc(-c3ccccc3)n2)cc1 ; c1ccc(-c2cc(-c3nc(-c4ccccc4)nc(-c4ccccc4)n3)cc(-c3cc4ccccc4c4ccccc34)c2)cc1]

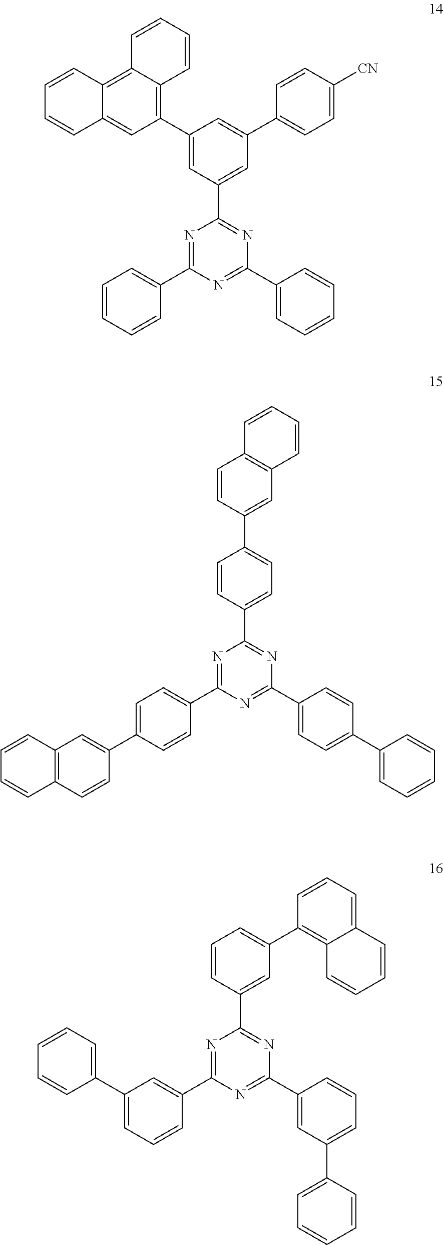 [SMILES: N#Cc1ccc(-c2cc(-c3nc(-c4ccccc4)nc(-c4ccccc4)n3)cc(-c3cc4ccccc4c4ccccc34)c2)cc1 ; c1ccc(-c2ccc(-c3nc(-c4ccc(-c5ccc6ccccc6c5)cc4)nc(-c4ccc(-c5ccc6ccccc6c5)cc4)n3)cc2)cc1 ; c1ccc(-c2cccc(-c3nc(-c4cccc(-c5ccccc5)c4)nc(-c4cccc(-c5cccc6ccccc56)c4)n3)c2)cc1]

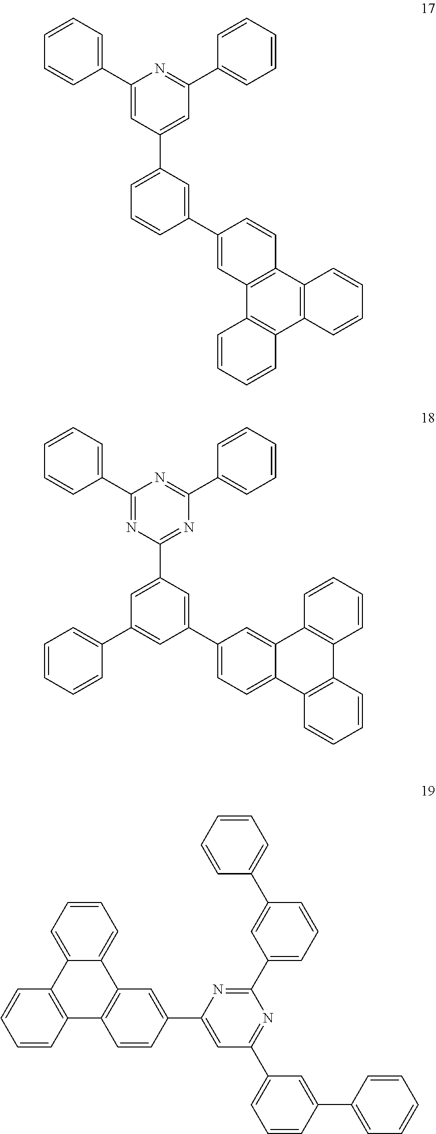

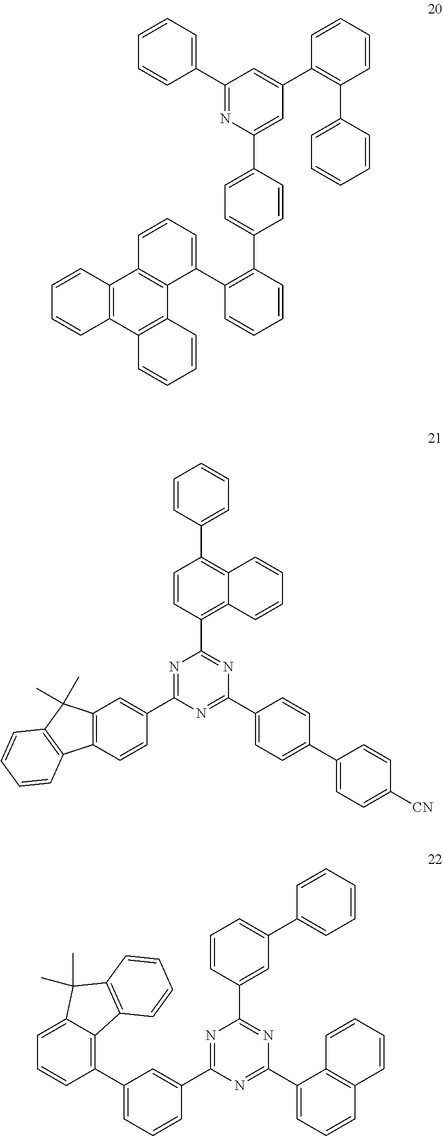 [SMILES: c1ccc(-c2cc(-c3ccccc3-c3ccccc3)cc(-c3ccc(-c4ccccc4-c4cccc5c6ccccc6c6ccccc6c45)cc3)n2)cc1 ; CC1(C)c2ccccc2-c2ccc(-c3nc(-c4ccc(-c5ccc(C#N)cc5)cc4)nc(-c4ccc(-c5ccccc5)c5ccccc45)n3)cc21 ; CC1(C)c2ccccc2-c2c(-c3cccc(-c4nc(-c5cccc(-c6ccccc6)c5)nc(-c5cccc6ccccc56)n4)c3)cccc21]

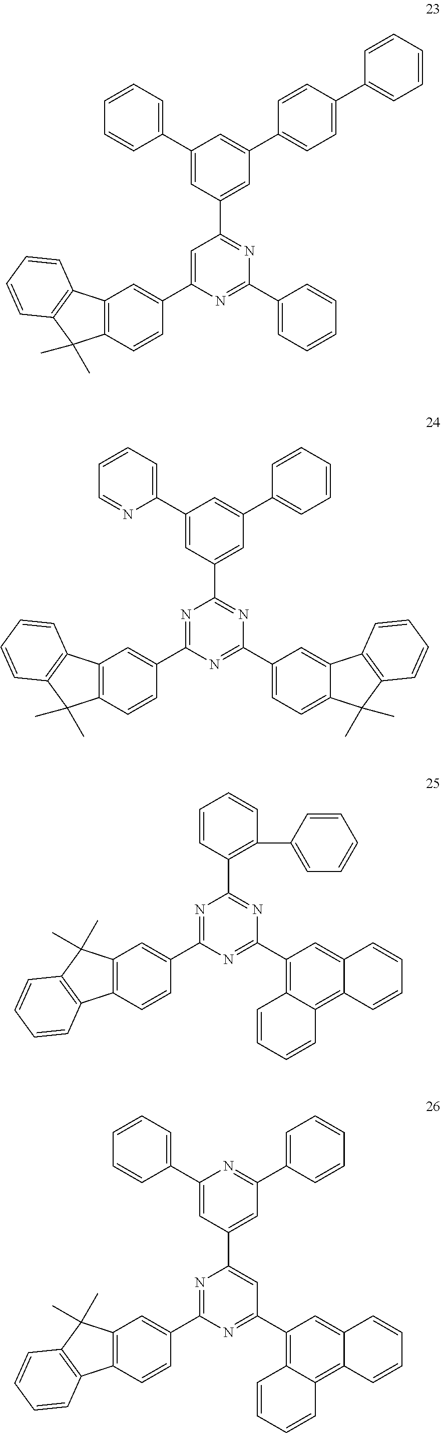 [SMILES: CC1(C)c2ccccc2-c2cc(-c3cc(-c4cc(-c5ccccc5)cc(-c5ccc(-c6ccccc6)cc5)c4)nc(-c4ccccc4)n3)ccc21 ; CC1(C)c2ccccc2-c2cc(-c3nc(-c4cc(-c5ccccc5)cc(-c5ccccn5)c4)nc(-c4ccc5c(c4)-c4ccccc4C5(C)C)n3)ccc21 ; CC1(C)c2ccccc2-c2ccc(-c3nc(-c4ccccc4-c4ccccc4)nc(-c4cc5ccccc5c5ccccc45)n3)cc21 ; CC1(C)c2ccccc2-c2ccc(-c3nc(-c4cc(-c5ccccc5)nc(-c5ccccc5)c4)cc(-c4cc5ccccc5c5ccccc45)n3)cc21]

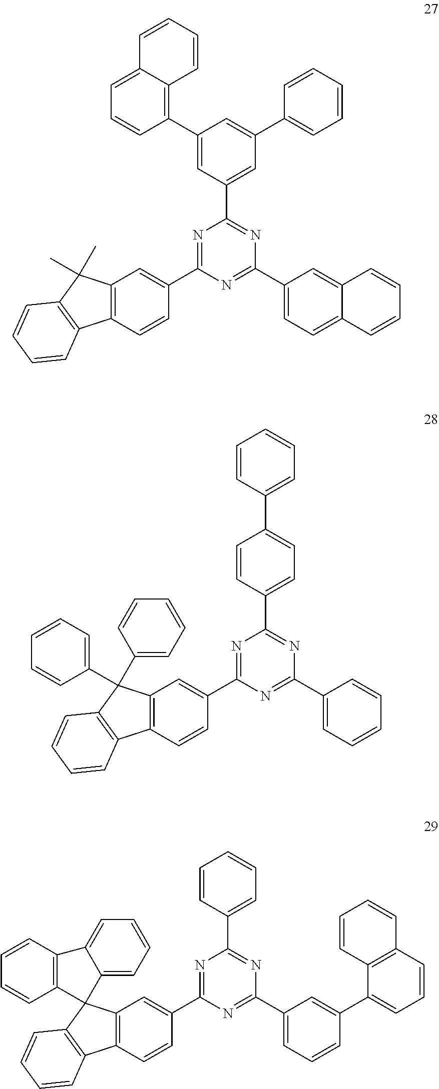 [SMILES: CC1(C)c2ccccc2-c2ccc(-c3nc(-c4cc(-c5ccccc5)cc(-c5cccc6ccccc56)c4)nc(-c4ccc5ccccc5c4)n3)cc21 ; c1ccc(-c2ccc(-c3nc(-c4ccccc4)nc(-c4ccc5c(c4)C(c4ccccc4)(c4ccccc4)c4ccccc4-5)n3)cc2)cc1 ; c1ccc(-c2nc(-c3cccc(-c4cccc5ccccc45)c3)nc(-c3ccc4c(c3)C3(c5ccccc5-c5ccccc53)c3ccccc3-4)n2)cc1]

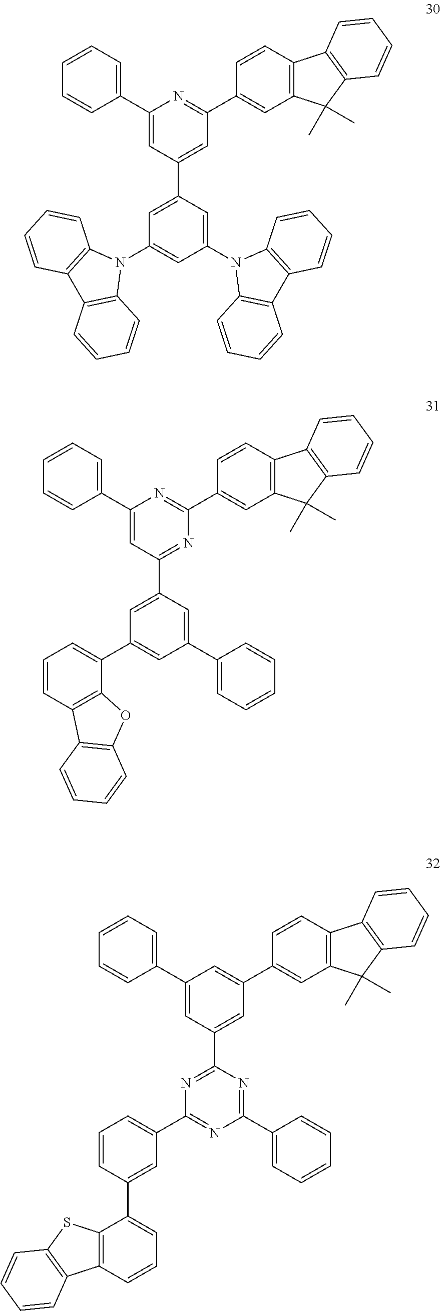 [SMILES: CC1(C)c2ccccc2-c2ccc(-c3cc(-c4cc(-n5c6ccccc6c6ccccc65)cc(-n5c6ccccc6c6ccccc65)c4)cc(-c4ccccc4)n3)cc21 ; CC1(C)c2ccccc2-c2ccc(-c3nc(-c4ccccc4)cc(-c4cc(-c5ccccc5)cc(-c5cccc6c5oc5ccccc56)c4)n3)cc21 ; CC1(C)c2ccccc2-c2ccc(-c3cc(-c4ccccc4)cc(-c4nc(-c5ccccc5)nc(-c5cccc(-c6cccc7c6sc6ccccc67)c5)n4)c3)cc21]

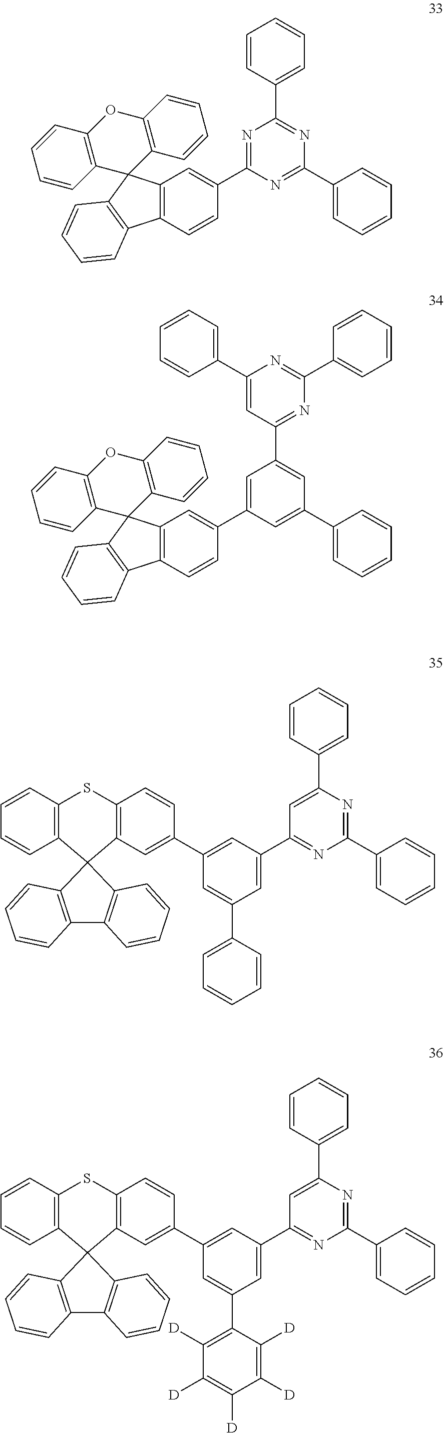 [SMILES: c1ccc(-c2nc(-c3ccccc3)nc(-c3ccc4c(c3)C3(c5ccccc5Oc5ccccc53)c3ccccc3-4)n2)cc1 ; c1ccc(-c2cc(-c3ccc4c(c3)C3(c5ccccc5Oc5ccccc53)c3ccccc3-4)cc(-c3cc(-c4ccccc4)nc(-c4ccccc4)n3)c2)cc1 ; c1ccc(-c2cc(-c3ccc4c(c3)C3(c5ccccc5S4)c4ccccc4-c4ccccc43)cc(-c3cc(-c4ccccc4)nc(-c4ccccc4)n3)c2)cc1 ; [2H]c1c([2H])c([2H])c(-c2cc(-c3ccc4c(c3)C3(c5ccccc5S4)c4ccccc4-c4ccccc43)cc(-c3cc(-c4ccccc4)nc(-c4ccccc4)n3)c2)c([2H])c1[2H]]

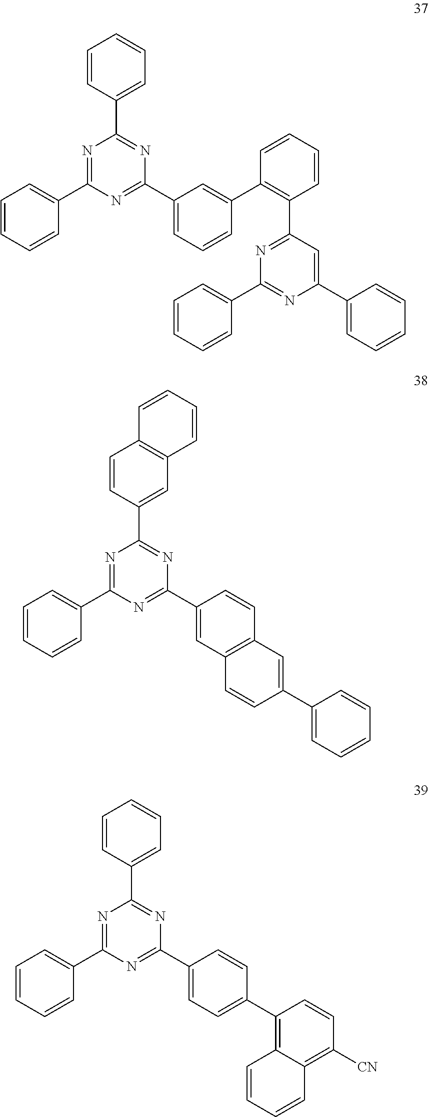 [SMILES: c1ccc(-c2cc(-c3ccccc3-c3cccc(-c4nc(-c5ccccc5)nc(-c5ccccc5)n4)c3)nc(-c3ccccc3)n2)cc1 ; c1ccc(-c2ccc3cc(-c4nc(-c5ccccc5)nc(-c5ccc6ccccc6c5)n4)ccc3c2)cc1 ; N#Cc1ccc(-c2ccc(-c3nc(-c4ccccc4)nc(-c4ccccc4)n3)cc2)c2ccccc12]

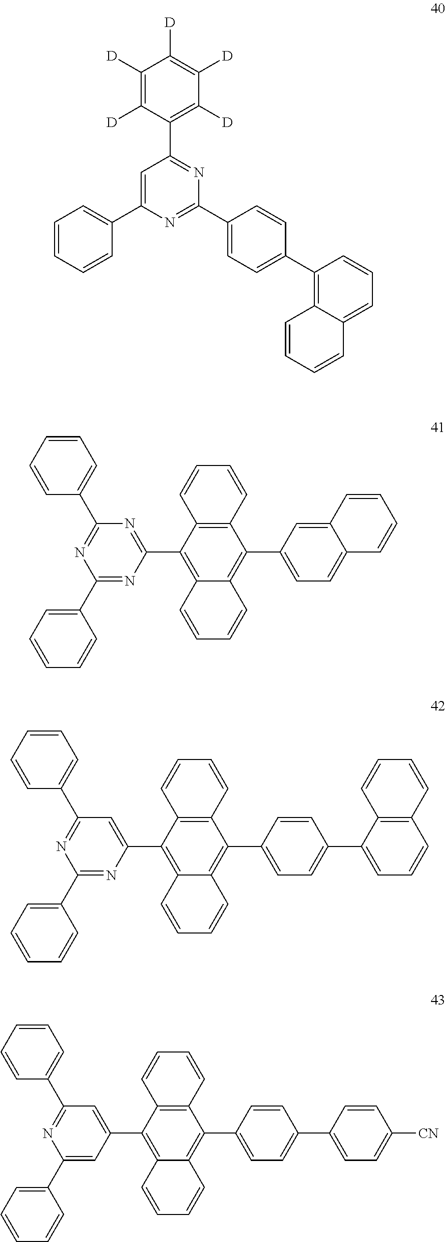 [SMILES: [2H]c1c([2H])c([2H])c(-c2cc(-c3ccccc3)nc(-c3ccc(-c4cccc5ccccc45)cc3)n2)c([2H])c1[2H] ; c1ccc(-c2nc(-c3ccccc3)nc(-c3c4ccccc4c(-c4ccc5ccccc5c4)c4ccccc34)n2)cc1 ; c1ccc(-c2cc(-c3c4ccccc4c(-c4ccc(-c5cccc6ccccc56)cc4)c4ccccc34)nc(-c3ccccc3)n2)cc1 ; N#Cc1ccc(-c2ccc(-c3c4ccccc4c(-c4cc(-c5ccccc5)nc(-c5ccccc5)c4)c4ccccc34)cc2)cc1]

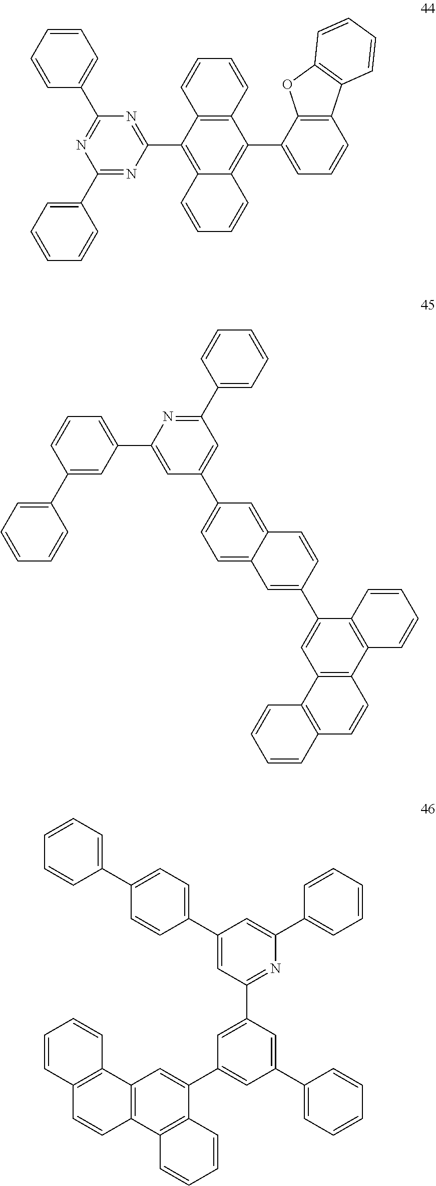 [SMILES: c1ccc(-c2nc(-c3ccccc3)nc(-c3c4ccccc4c(-c4cccc5c4oc4ccccc45)c4ccccc34)n2)cc1 ; c1ccc(-c2cccc(-c3cc(-c4ccc5cc(-c6cc7c8ccccc8ccc7c7ccccc67)ccc5c4)cc(-c4ccccc4)n3)c2)cc1 ; c1ccc(-c2ccc(-c3cc(-c4ccccc4)nc(-c4cc(-c5ccccc5)cc(-c5cc6c7ccccc7ccc6c6ccccc56)c4)c3)cc2)cc1]

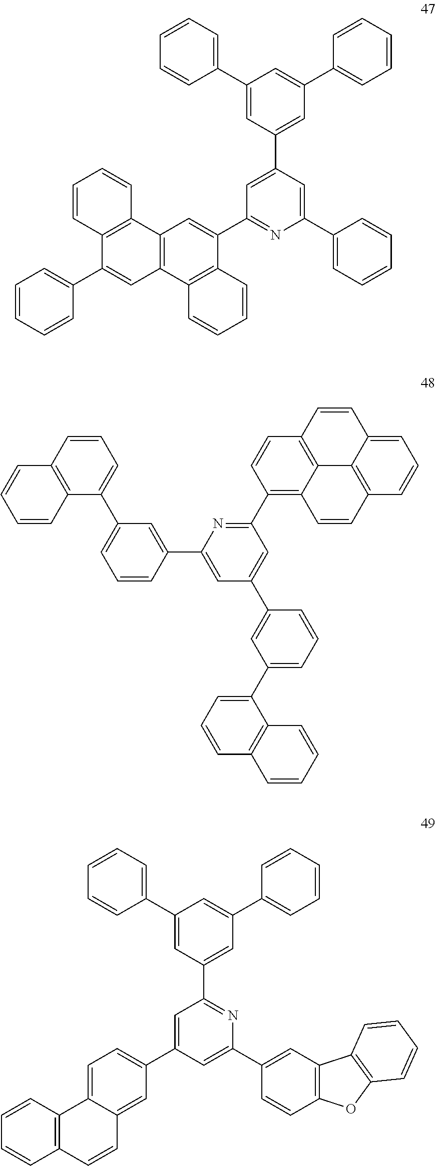 [SMILES: c1ccc(-c2cc(-c3ccccc3)cc(-c3cc(-c4ccccc4)nc(-c4cc5c6ccccc6c(-c6ccccc6)cc5c5ccccc45)c3)c2)cc1 ; c1cc(-c2cc(-c3cccc(-c4cccc5ccccc45)c3)nc(-c3ccc4ccc5cccc6ccc3c4c56)c2)cc(-c2cccc3ccccc23)c1 ; c1ccc(-c2cc(-c3ccccc3)cc(-c3cc(-c4ccc5c(ccc6ccccc65)c4)cc(-c4ccc5oc6ccccc6c5c4)n3)c2)cc1]

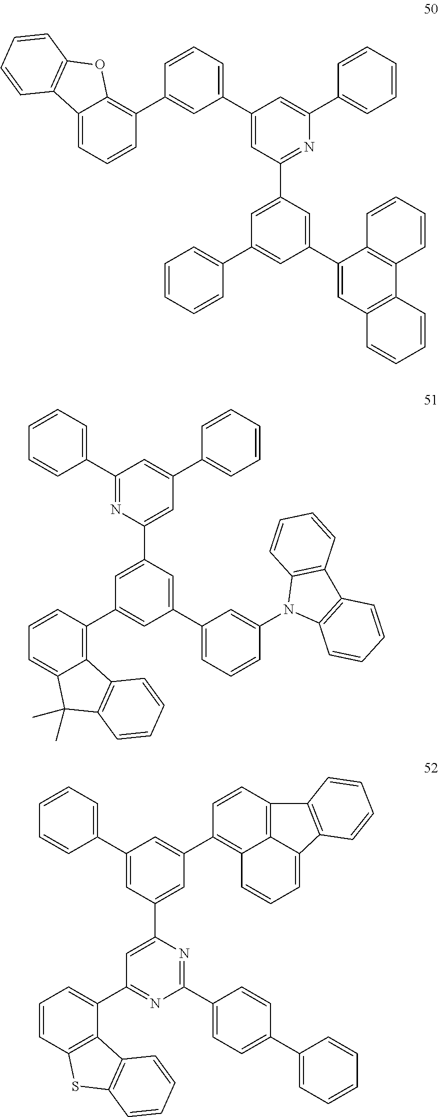 [SMILES: c1ccc(-c2cc(-c3cc(-c4cccc(-c5cccc6c5oc5ccccc56)c4)cc(-c4ccccc4)n3)cc(-c3cc4ccccc4c4ccccc34)c2)cc1 ; CC1(C)c2ccccc2-c2c(-c3cc(-c4cccc(-n5c6ccccc6c6ccccc65)c4)cc(-c4cc(-c5ccccc5)cc(-c5ccccc5)n4)c3)cccc21 ; c1ccc(-c2ccc(-c3nc(-c4cc(-c5ccccc5)cc(-c5ccc6c7c(cccc57)-c5ccccc5-6)c4)cc(-c4cccc5sc6ccccc6c45)n3)cc2)cc1]

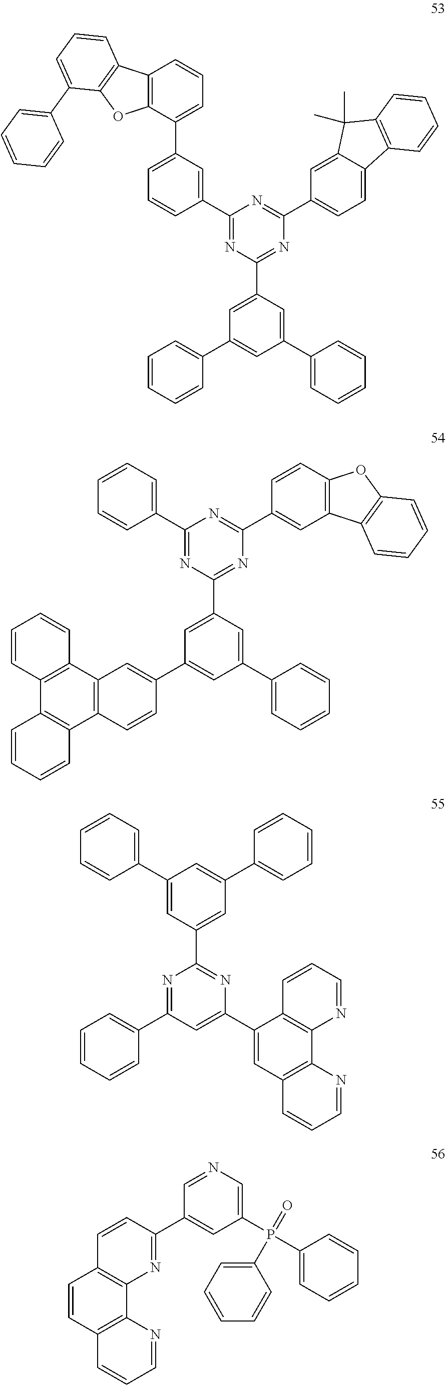 [SMILES: CC1(C)c2ccccc2-c2ccc(-c3nc(-c4cc(-c5ccccc5)cc(-c5ccccc5)c4)nc(-c4cccc(-c5cccc6c5oc5c(-c7ccccc7)cccc56)c4)n3)cc21 ; c1ccc(-c2cc(-c3ccc4c5ccccc5c5ccccc5c4c3)cc(-c3nc(-c4ccccc4)nc(-c4ccc5oc6ccccc6c5c4)n3)c2)cc1 ; c1ccc(-c2cc(-c3ccccc3)cc(-c3nc(-c4ccccc4)cc(-c4cc5cccnc5c5ncccc45)n3)c2)cc1 ; O=P(c1ccccc1)(c1ccccc1)c1cncc(-c2ccc3ccc4cccnc4c3n2)c1]

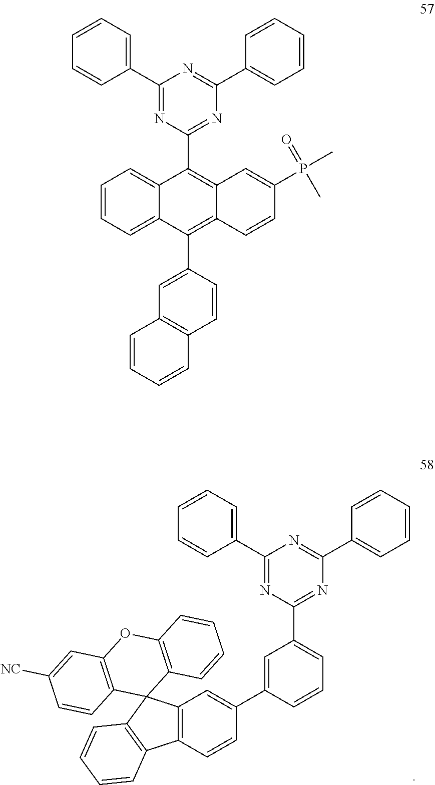 [SMILES: CP(C)(=O)c1ccc2c(-c3ccc4ccccc4c3)c3ccccc3c(-c3nc(-c4ccccc4)nc(-c4ccccc4)n3)c2c1 ; N#Cc1ccc2c(c1)Oc1ccccc1C21c2ccccc2-c2ccc(-c3cccc(-c4nc(-c5ccccc5)nc(-c5ccccc5)n4)c3)cc21]

17. An electronic device comprising:
a red light-emitting region, a green light-emitting region, and a blue light-emitting region that are separated from each other in a plan view;
a circuit layer disposed on a base layer; and
a display layer disposed on the circuit layer, wherein
the display layer includes:
a red light-emitting element disposed in the red light-emitting region;
a green light-emitting element disposed in the green light-emitting region; and
a blue light-emitting element disposed in the blue light-emitting region, the red light-emitting element, the green light-emitting element, and the blue light-emitting element each comprises:
a first electrode;
a second electrode facing the first electrode;
a lower emission structure disposed between the first electrode and the second electrode, the lower emission structure including a first lower functional layer, a first emission layer, and a first upper functional layer that are sequentially stacked;
an upper emission structure disposed on the lower emission structure, the upper emission structure including a second lower functional layer, a second emission layer, and a second upper functional layer that are sequentially stacked; and
a charge generation layer disposed between the lower emission structure and the upper emission structure, the charge generation layer including an n-type charge generation layer and a p-type charge generation layer, and
the electronic device satisfies Expression 1:
$$50 nm \geq {d}_{TOP} > {d}_{LOW} > 15 nm \qquad [ Expression 1 ]$$
wherein in Expression 1,
d_{LOW} is a sum of a thickness of the first upper functional layer and a thickness of the n-type charge generation layer, and
d_{TOP} is a thickness of the second upper functional layer.

18. The electronic device of claim 17, wherein
the first upper functional layer comprises:
a first electron transport layer directly disposed under the n-type charge generation layer; and
a first electron transport auxiliary layer directly disposed under the first electron transport layer,
the second upper functional layer comprises:
a second electron transport auxiliary layer directly disposed on the second emission layer; and
a second electron transport layer directly disposed on the second electron transport auxiliary layer, and
three or more layers selected from the first electron transport layer, the first electron transport auxiliary layer, the n-type charge generation layer, the second electron transport auxiliary layer, and the second electron transport layer each independently comprise an electron transport material including a monocyclic 6-membered heteroaryl group that includes N as a ring-forming atom.

19. The electronic device of claim 18, wherein the electron transport material that is comprised in at least one layer among the selected three or more layers includes a monocyclic 6-membered heteroaryl group that includes N as a ring-forming atom and a condensed ring that includes eight or more ring-forming carbon atoms.

20. The electronic device of claim 17, wherein the first lower functional layer, the first upper functional layer, the charge generation layer, the second lower functional layer, and the second upper functional layer are each disposed as a common layer in the red light-emitting region, the green light-emitting region, and the blue light-emitting region.
